(19) United States
(12) Patent Application Publication
(10) Pub. No.: US 2014/0289446 A1
(43) Pub. Date: Sep. 25, 2014

(54) MEMORY SYSTEM AND MEMORY

(71) Applicant: KABUSHIKI KAISHA TOSHIBA, Tokyo (JP)

(72) Inventor: Ryousuke TAKIZAWA, Naka-gun (JP)

(21) Appl. No.: 14/018,169

(22) Filed: Sep. 4, 2013

Related U.S. Application Data
(60) Provisional application No. 61/803,983, filed on Mar. 21, 2013.

(51) Int. Cl. G11C 7/10; G06F 12/02

(52) U.S. Cl. CPC G11C 7/1072; G06F 12/0238
USPC 711/102; 711/104; 711/167

(57) ABSTRACT

According to one embodiment, a memory system includes a memory and a controller configured to control the memory. The memory includes a semiconductor memory region in which data rewrite is executed by an instruction of the controller, a timing determination module configured to derive a command input timing to the memory, based on the instruction and a clock which are received from the controller, and a status register configured to store the command input timing to the memory, which is derived by the timing determination module.

### CROSS-REFERENCE TO RELATED APPLICATIONS

This application claims the benefit of U.S. Provisional Application No. 61/803,983, filed Mar. 21, 2013, the entire contents of which are incorporated herein by reference.

### FIELD

Embodiments described herein relate generally to a high-quality memory system and memory.

### BACKGROUND

In recent years, there has been the advent of a nonvolatile large-capacity working memory which is capable of high-speed read/write and includes a nonvolatile DDR (Double Data Rate) interface, and this working memory, by a single unit, can replace an existing nonvolatile ROM and an existing nonvolatile large-capacity working memory.

### BRIEF DESCRIPTION OF THE DRAWINGS

FIG. 1 is a schematic view which schematically illustrates a relationship in connection between a memory chip and a memory controller according to an embodiment.

FIG. 2 is a perspective view which schematically illustrates a relationship in connection between the memory chip and memory controller according to the embodiment.

FIG. 3 is a block diagram illustrating a memory chip of a magnetic random access memory (hereinafter referred to as “MRAM”) according to the embodiment.

FIG. 4 is a plan view illustrating an example of layout of memory array regions and a periphery circuit of a memory chip according to the embodiment.

FIG. 5A is a block diagram illustrating a basic structure of a memory array region of a memory chip, and FIG. 5B is a block diagram illustrating a basic structure of a memory array region of a memory chip.

FIG. 6 is a circuit diagram illustrating a memory cell array of an MRAM and peripheral parts thereof according to the embodiment.

FIG. 7A is a circuit diagram illustrating the length of bit lines of the memory array of the memory chip, and FIG. 7B is a circuit diagram illustrating the length of bit lines of the memory array of the memory chip.

FIG. 8 is a cross-sectional view illustrating a structure of a memory cell provided in the memory array of the MRAM of the embodiment.

FIG. 9A is a plan view illustrating a layout of timing controllers of the memory chip, and FIG. 9B is a plan view illustrating a layout of timing controllers of the memory chip.

FIG. 10A is a plan view illustrating a layout of timing controllers of the memory chip, and FIG. 10B is a plan view illustrating a layout of timing controllers of the memory chip.

FIG. 11 is a flowchart illustrating a basic operation when the memory chip derives latency by itself at a power-on time of the memory chip or at a power-down restoration time.

FIG. 12A is a timing chart relating to a read operation of the memory chip according to the embodiment, FIG. 12B is a timing chart illustrating an internal timing, and FIG. 12C is a view illustrating a relationship between a clock frequency to the memory chip and nRCD.

FIG. 13A is a timing chart relating to a write operation of the memory chip according to the embodiment, FIG. 13B is a timing chart illustrating an internal timing, and FIG. 13C is a view illustrating a relationship between a clock frequency to the memory chip and nWR.

FIG. 14 is a timing chart illustrating a timing between a memory controller, a memory chip and another memory chip.

FIG. 15 is a view illustrating a variation in latency when an external clock frequency or a temperature of the memory chip has varied.

FIG. 16 is a graph illustrating temperature characteristics of an MRAM.

FIG. 17A is a circuit diagram illustrating a concrete structure of a clock comparator, FIG. 17B is a timing chart relating to an operation of the clock comparator, and FIG. 17C is a view illustrating a relationship between a count number and time.

FIG. 18 is a timing chart illustrating an example of exchange of commands and data between a memory controller, a memory chip and another memory chip.

FIG. 19 is a circuit diagram illustrating a basic structure of a clock comparator according to an embodiment.

FIG. 20A is a circuit diagram illustrating a basic structure of a self reset timer according to an embodiment, and FIG. 20B is a timing chart illustrating a basic operation of the self reset timer according to the embodiment.

FIG. 21 is a flowchart illustrating a basic operation of a memory chip using the self reset timer according to the embodiment.

FIG. 22A is a plan view of a memory chip according to the embodiment, and FIG. 22B is a cross-sectional view of the memory chip and memory controller according to the embodiment.

FIG. 23A is a plan view of a memory chip according to the embodiment, and FIG. 23B is a cross-sectional view of the memory chip and memory controller according to the embodiment.

FIG. 24A is a plan view of a memory chip according to the embodiment, and FIG. 24B is a cross-sectional view of the memory chip and memory controller according to the embodiment.

FIG. 25A is a plan view of a memory chip and an IF controller according to the embodiment, and FIG. 25B is a cross-sectional view of the memory chip, IF controller and memory controller according to the embodiment.

FIG. 26 is a perspective view of the memory chip and memory controller according to the embodiment.

FIG. 27 is a cross-sectional view of the memory chip and memory controller according to the embodiment.

### DETAILED DESCRIPTION

In general, according to one embodiment, a memory system includes a memory and a controller configured to control the memory. The memory includes a semiconductor memory region in which data rewrite is executed by an instruction of the controller; a timing determination module configured to derive a command input timing to the memory, based on the instruction and a clock which are received from the controller; and a status register configured to store the command input timing to the memory, which is derived by the timing determination module. The controller is configured to read out the command input timing from the status register and to issue a command to the memory, based on the command input timing which is acquired.

Embodiments will now be described in detail with reference to the accompanying drawings. In the description below, structural elements having substantially the same function or structure are denoted by like reference numerals, and an overlapping description is given only where necessary. The embodiments to be described below merely illustrate, by way of example, devices and methods for embodying the technical concepts of the embodiments, and the technical concepts of the embodiments do not specify the material, shape, structure, arrangement, etc. of structural components to the examples described below. The technical concepts of the embodiments can be variously altered in the patent claims.

### First Embodiment

### Basic Structure of Memory Chip and Memory Controller

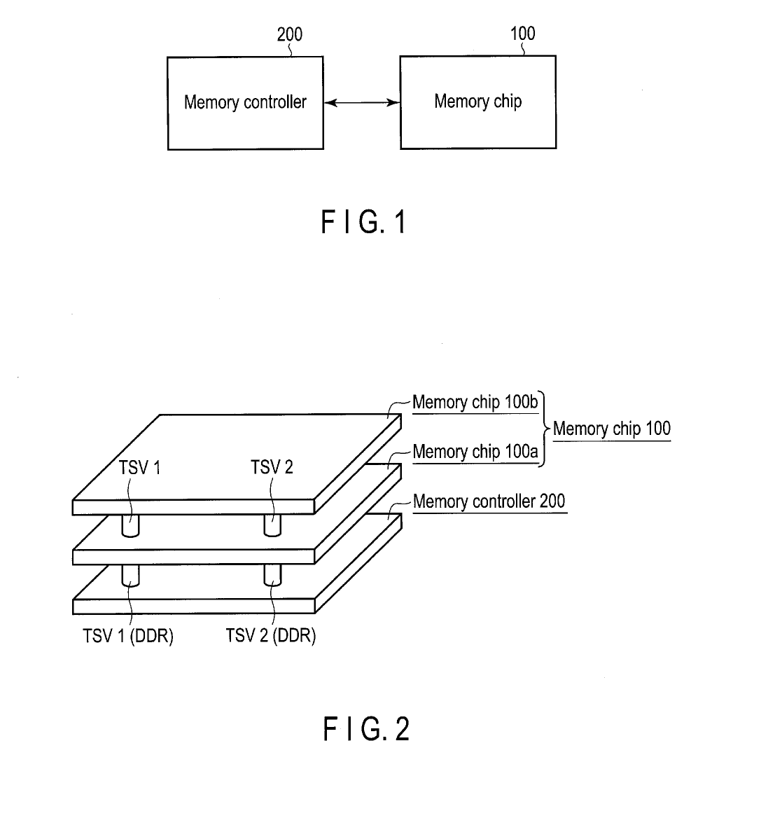

To begin with, referring to FIG. 1 and FIG. 2, a schematic description is given of a memory chip 100 and a memory controller 200 according to a first embodiment is described. FIG. 1 is a schematic view which schematically illustrates a relationship in connection between the memory chip 100 and memory controller 200 according to the first embodiment. FIG. 2 is a perspective view which schematically illustrates a relationship in connection between the memory chip 100 and memory controller 200 according to the first embodiment.

As illustrated in FIG. 1, the memory chip 100 is connected to the memory controller 200. The memory chip 100 operates according to an instruction (command) from the memory controller 200.

In addition, as shown in FIG. 2, the memory chip 100 according to the embodiment includes, for example, a memory chip 100a and a memory chip 100b having different capabilities, and is stacked on the memory controller 200 by using a TSV (Through Silicon Via) technology. In the present embodiment, as an input/output interface, a DDR (Double Data Rate) interface is adopted. In the meantime, when the memory chip 100a and memory chip 100b are not discriminated, these memory chips are simply referred to as “memory” or “memory chip 100”.

<Configuration of MEMORY CHIP>

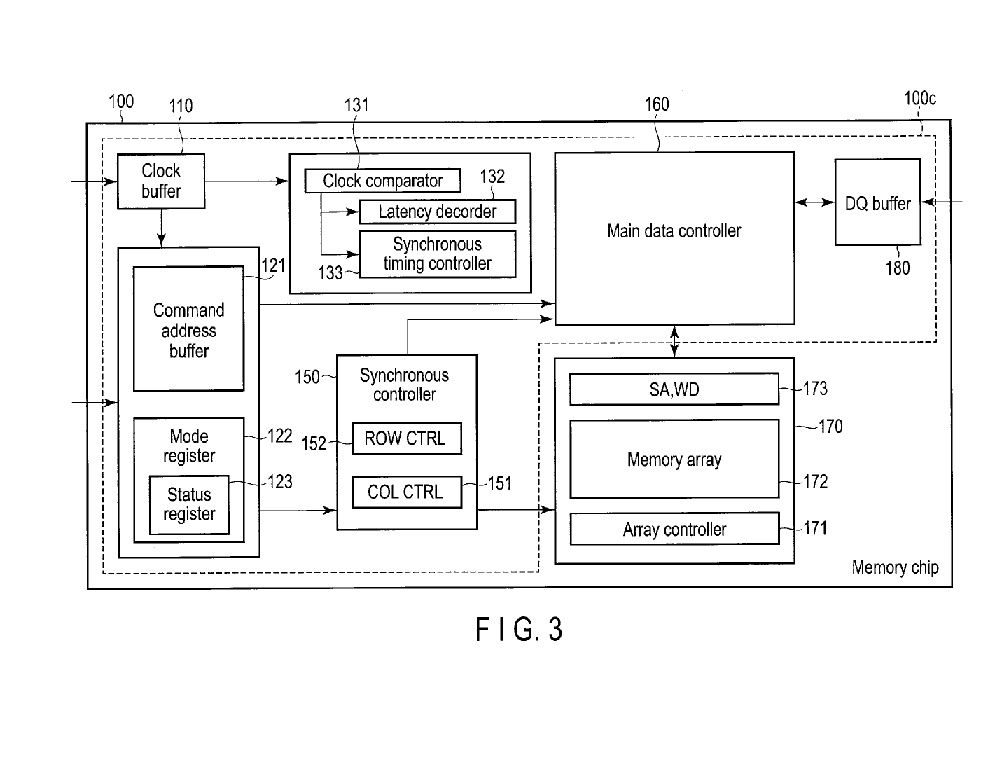

Next, referring to FIG. 3, a schematic description is given of the basic structure of the memory chip 100 according to the embodiment. FIG. 3 is a block diagram illustrating a memory chip 100 of a magnetic random access memory (hereinafter referred to as “MRAM”) according to the first embodiment. Incidentally, this embodiment is also applicable to memories other than the MRAM, such as a memory using a resistive element, and a ferroelectric memory (e.g. FeRAM).

As illustrated in FIG. 3, the memory chip 100 includes a periphery circuit 100c and a memory array region 170.

In addition, as shown in FIG. 3, the periphery circuit 100c includes a clock buffer 110, a command address buffer 121, a mode register 122, a clock comparator 131, a latency decoder 132, a synchronous timing controller 133, a synchronous controller 150, a main data controller 160, and a DQ buffer 180.

The clock buffer 110 receives a clock signal from the external memory controller 200, and supplies the clock signal to other periphery circuit components which operate in sync with the clock signal. The clock, which is received from the memory controller 200, is also referred to as “external clock” or the like.

The clock comparator 131 is a circuit which derives an internal delay interval (latency) in the memory chip 100, based on a request (e.g. a mode register write command) from the memory controller 200. The clock comparator 131 detects the time of the external clock, with a precision on the order of 10 to more than 100 times. The clock comparator 131 determines which of discrete use frequency choices specified in the interface the present frequency corresponds to. The clock comparator 131 determines the internal delay interval (latency) in accordance with the determined frequency. In order to inform the memory controller 200 of the internally set interval, the clock comparator 131 calculates a latency corresponding to a read/write time (stored in the latency decoder 132) which corresponds to the operation frequency that is set in the mode register 122, and sets the latency in a status register 123 for notification. Incidentally, a concrete example, etc. of the method of deriving the latency will be described later.

The latency decoder 132 stores a time which is needed for write in the memory area region 170 of memory chip 100, or a time which is needed for read from the memory area region 170 of memory chip 100. Aside from this, the latency decoder 132 may have a function of converting an operation state of the memory chip 100, such as an ambient temperature (temperature of memory chip 100) or an operation voltage, to time.

The memory chip 100 includes a temperature detection circuit and a voltage detection circuit (not shown), and the clock comparator 131 calculates a latency in accordance with MRAM characteristics corresponding to the temperature and voltage. Incidentally, the combination of the clock comparator 131 and latency decoder 132 is also referred to as “timing determination module”.

The synchronous timing controller 133 controls the synchronous controller 150, etc. in accordance with the external clock.

The command address buffer 121 receives commands indicative of various operations such as a read operation and a write operation, controls a column controller 151 and a row controller 152 in accordance with these commands. In addition, the command address buffer 121 receives a row address and a column address, decodes these addresses, and transfers these addresses the column controller 151 and row controller 152.

In the mode register 122, the operation mode of the memory chip 100 is set by the memory controller 200. In addition, the mode register 122 includes the status register 123 for storing latency (command interval) information such as nRCD (RAS to CAS Latency), nRP (Row Precharge Latency), nWR (Write Recovery Latency), nRL (Read Latency) and nWL (Write Latency). In the present embodiment, the command issuance interval (latency) for the memory chip 100 is stored not by time, but by a clock number (The Number of Clock) which is derived by the memory chip. By a request (e.g. mode register read command) of the memory controller 200, the mode register 122 notifies the memory controller 200 of the value (read time, write time) which is set in the status register 123.

The main data controller 160 transfers, under the control of the column controller 151, the data, which has been received from the DQ buffer 180, to a write driver so as to write the data in a desired column, or the main data controller 160 transfers, under the control of the column controller 151, the data, which has been read out from a desired column, to the DQ buffer 180. In addition, the main data controller 160 is configured to prohibit data write in accordance with write mask data WM.

The synchronous controller 150 includes a column controller 151 and a row controller 152.

The column controller 151 operates a sense amplifier, a write driver and a column control circuit (not shown) so as to selectively drive a bit line BL of a desired column in accordance with a column address.

The row controller 152 operates a row control circuit (not shown) so as to selectively drive a desired word line WL in accordance with a row address.

In addition, the memory array region 170 includes an array controller 171, a memory array 172 and a sense amplifier/write driver 173.

Although a detailed description is omitted in this specification, a plurality of memory array regions 170 are provided, and each memory array region is also called “bank”.

The array controller 171 executes overall control of the memory array 172.

The memory array 172 includes a plurality of memory cells MC which are two-dimensionally arranged in a matrix. Each memory cell MC is arranged in association with an intersection between a bit line BL (or bit line pair) and a word line WL. The bit line BL extends in a column direction. The word line WL extends in a row direction which is perpendicular to the column direction.

The sense amplifier/write driver 173 includes a sense amplifier SA and a write driver WD. The sense amplifier SA is connected to the memory cell MC via the bit line BL, and is configured to detect data of the memory cell MC. The write driver WD is connected to the memory cell MC via the bit line BL, and is configured to write data in the memory cell MC.

The DQ buffer 180 temporarily stores read data via a DQ pad (not shown), and outputs the read data to the outside of the memory chip 100. Alternatively, the DQ buffer 180 receives write data via the DQ pad from the outside of the memory chip 100, and temporarily stores the write data. The DQ buffer 180 receives write mask data WM via a WM pad (not shown). In the meantime, the MRAM according to the embodiment, which includes the DDR-type interface, receives write mask data WM, as well as write data, at a time of data write. The write mask data WM is a command which instructs whether write data of predetermined bits is to be actually written. The write mask data WM can instruct whether data write is necessary or not in units of byte data.

In the meantime, each of the memory chip 100a and memory chip 100b includes an independent periphery circuit 100c.

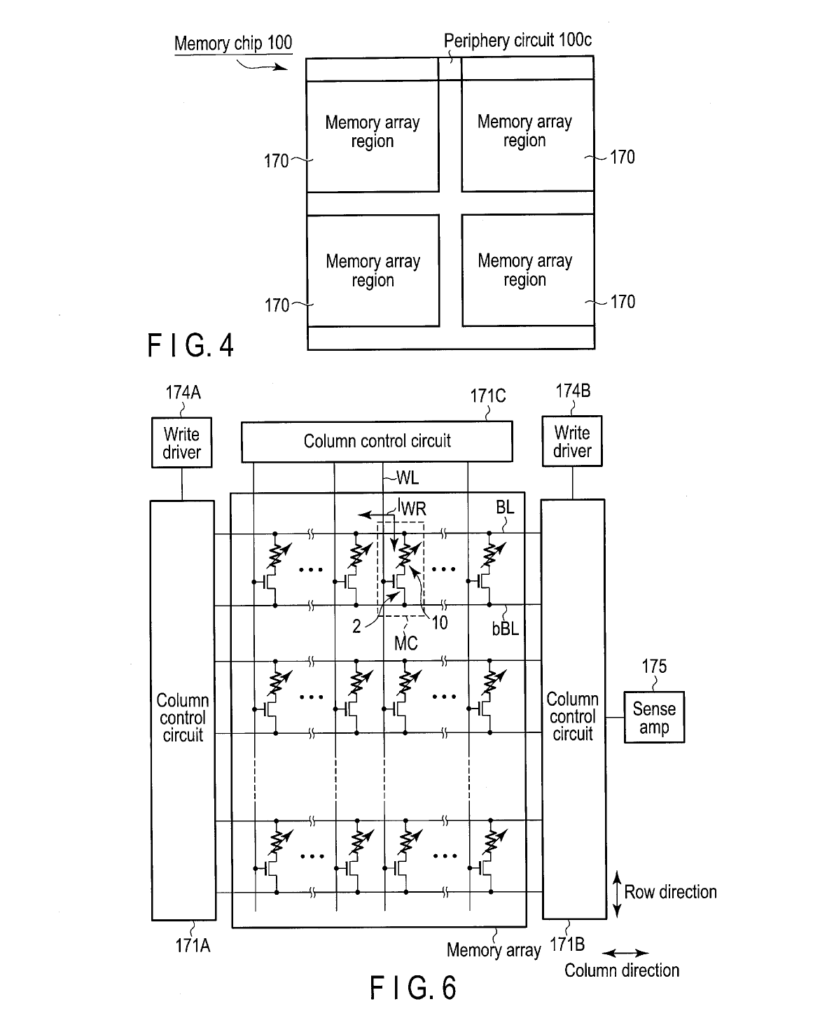

Next, referring to FIG. 4, a description is given of an example of layout of the memory array region 170 and periphery circuit 100c of the memory chip 100 according to the embodiment. FIG. 4 is a plan view illustrating an example of layout of the memory array region 170 and periphery circuit 100c of the memory chip 100 according to the embodiment.

As illustrated in FIG. 4, the memory chip 100 according to the embodiment includes four divided memory array regions 170. In addition, the periphery circuit 100c, for example, is provided at an end portion of the memory chip 100.

The memory controller 200 has a function of confirming with the memory chip 100 about the read time and write time. In addition, the memory controller 200 has a redundant configuration in order to enable different latency settings for individual memory chips 100.

Specifically, the memory chip 100 sets read/write latency in response to a request from the memory controller 200.

The memory controller 200 has a function of issuing a mode register read command to the memory chip 100, thereby inquiring about the read/write latency.

The memory controller 200 has an independent control function for each memory chip 100 in order to handle chips with different specific latencies.

<Configuration of MEMORY Array>

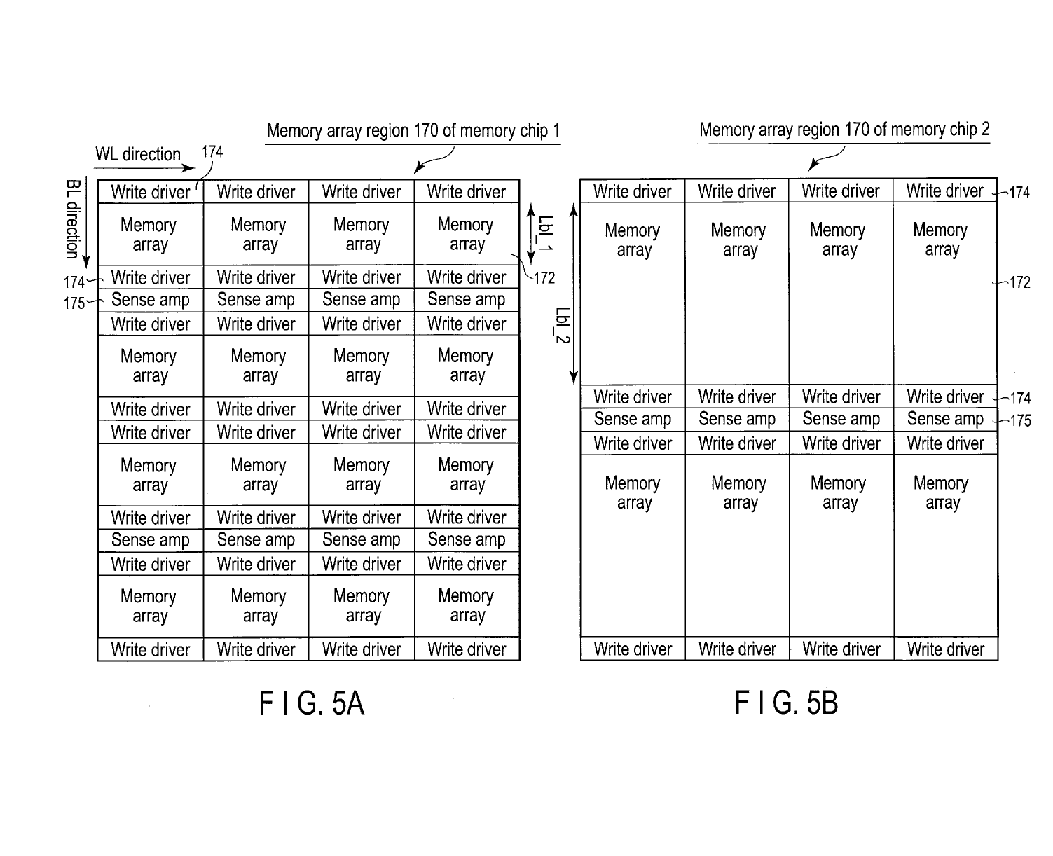

Next, referring to FIG. 5A and FIG. 5B, a description is given of a basic structure of the memory array 170 according to the embodiment. FIG. 5A is a block diagram illustrating a basic structure of the memory array region 170 of the memory chip 100a. FIG. 5B is a block diagram illustrating a basic structure of the memory array region 170 of the memory chip 100b.

As illustrated in FIG. 5A, for example, a memory array 172 is sandwiched between write drivers 174 in the bit line direction, and a sense amplifier 175 is provided adjacent to one of the write drivers 174. In addition, 16 memory arrays 172 are provided in the memory array region 170 of the memory chip 100a according to the embodiment. The length of one memory array 172 in the bit line direction is Lb1_{—}1.

As illustrated in FIG. 5B, 8 memory arrays 172 are provided in the memory array region 170 of the memory chip 100b according to the embodiment. The length of one memory array 172 in the bit line direction is Lb1_{—}2 (Lb1_{—}1<Lb1_{—}2). In short, the length in the bit line direction of the memory array 172 of the memory chip 100b is greater than the length in the bit line direction of the memory array 172 of the memory chip 100a.

<Circuit Configuration of MEMORY Array>

Next, referring to FIG. 6, a description is given of a circuit configuration of a memory cell array of the MRAM and peripheral parts thereof according to the first embodiment. FIG. 6 is a circuit diagram illustrating a memory cell array of the MRAM and peripheral parts thereof according to the first embodiment.

As illustrated in FIG. 6, the memory array 172 includes a plurality of memory cells MC. The memory cells MC are arrayed in the memory array 172. In the memory array 172, a plurality of bit lines BL, bBL and a plurality of word lines WL are provided. The bit lines BL, bBL extend in the column direction, and the word lines WL extend in the row direction. Two bit lines BL, bBL constitutes a single bit line pair.

The memory cells MC are connected to the bit lines BL, bBL and word lines WL. A plurality of memory cells MC, which are arranged in the column direction, are connected to a common bit line pair BL, bBL. A plurality of memory cells MC, which are arranged in the row direction, are connected to a common word line WL.

The memory cell MC includes, for example, one MTJ element 10 as a memory element, and one select switch 2.

The select switch 2 is, for example, a field-effect transistor. In the description below, the field-effect transistor functioning as the select switch 2 is referred to as “select transistor 2”.

One end of the MTJ element 10 is connected to the bit line BL, and the other end of the MTJ element 10 is connected to one end (source/drain) of the current path of the select transistor 2. The other end (drain/source) of the current path of the select transistor 2 is connected to the bit line bBL. A control terminal (gate) of the select transistor 2 is connected to the word line WL.

One end of the word line WL is connected to a row control circuit 171C. The row control circuit 171C controls activation/deactivation of the word line WL, based on an address signal from the outside.

One end and the other end of the bit line BL, bBL are connected to column control circuits 171A and 171B. The column control circuits 171A and 171B control activation/deactivation of the bit line BL, bBL, based on an address signal from the outside.

Write drivers 174A and 174B are connected to one end and the other end of the bit line BL, bBL, via the column control circuits 171A and 171B. The write driver 174A, 174B includes a source circuit such as a current source or voltage source for generating a write current, and a sink circuit for taking in the write current.

In an STT (Spin Transfer Torque)-type MRAM, at a time of data write, the write driver 174A, 174B supplies a write current to a memory cell (hereinafter referred to as “selected cell”) which is selected from the outside.

When data is written in the MTJ element 10, the write drivers 174A, 174B cause a write current to flow in the MTJ element 10 in the memory cell MC in two directions. Specifically, a write current from the bit line BL to the bit line bBL or a write current from the bit line bBL to the bit line BL is output from the write driver 174A, 174B, in accordance with data which is to be written in the MTJ element 10.

The sense amplifier 175 is connected to either one end or the other end of the bit line BL, bBL, via the column control circuit 171A, 171B. The sense amplifier 175 detects and amplifies a voltage source or a current source for generating a read current, or a read signal, and temporarily stores data. When data is read from the MTJ element 10, the sense amplifier 175 supplies a read current to a selected cell. The current value of the read current is lower than the current value (magnetization reversal threshold) of the write current, so that the magnetization of a recording layer may not be reversed by the read current.

In accordance with the magnitude of the resistance value of the MTJ element 10 to which the read current is supplied, the current value or potential at a read node varies. Based on the amount of variation (read signal, read output) corresponding to the magnitude of the resistance value, the data stored in the MTJ element 10 is discriminated.

In the meantime, in the present embodiment, the sense amplifier 175 is provided on one end side in the column direction, but two read-out circuits may be provided on one end and the other end in the column direction.

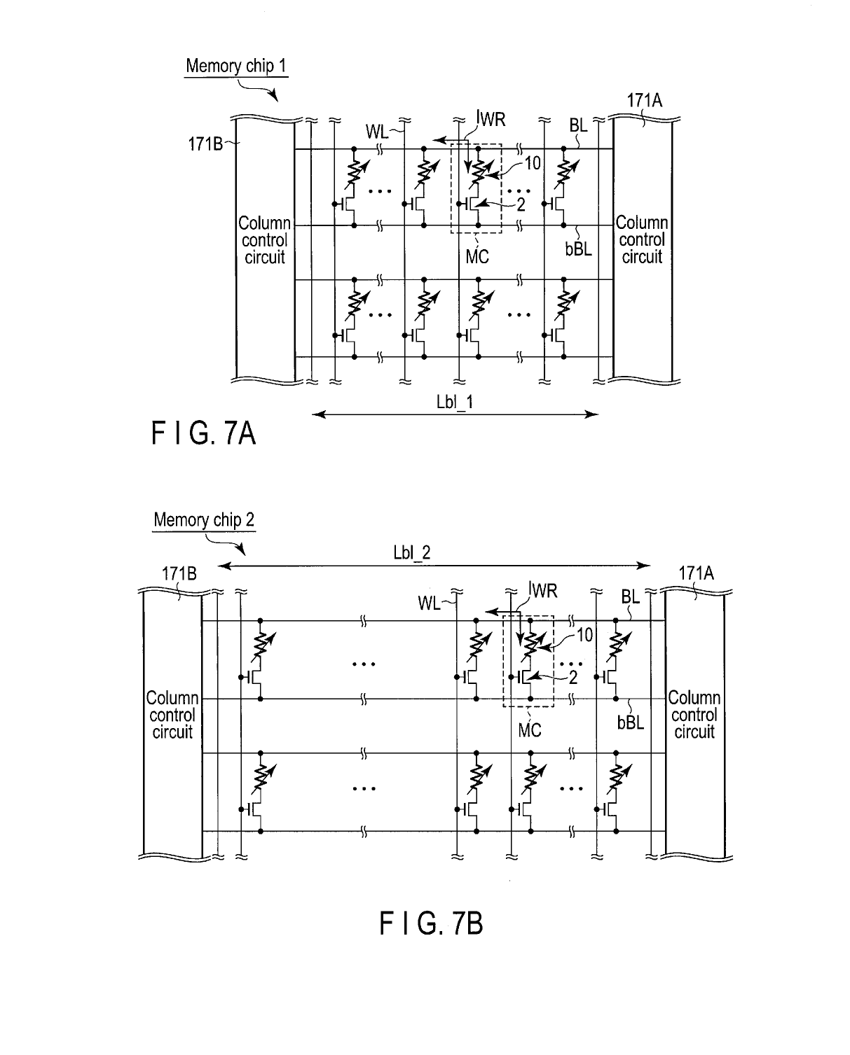

Next, referring to FIG. 7A and FIG. 7B, a schematic description is given of the length Lbl_{—}2 of the bit line BL of the memory array 172 of the memory chip 100b and the length Lbl_{—}1 of the bit line BL of the memory array 172 of the memory chip 100a. FIG. 7A is a circuit diagram illustrating the length Lbl_{—}1 of the bit line BL of the memory array 172 of the memory chip 100a, and FIG. 7B is a circuit diagram illustrating the length Lbl_{—}2 of the bit line BL of the memory array 172 of the memory chip 100b.

In addition, as illustrated in FIG. 7A and FIG. 7B, the length Lbl_{—}2 of the bit line BL of the memory array 172 of the memory chip 100b is greater than the length Lbl_{—}1 of the bit line BL of the memory array 172 of the memory chip 100a.

In the meantime, the read operation time in the MRAM is a time until forming a current path to only a specific cell by an activation signal and taking out a signal. As the parasitic resistance and parasitic capacitance of the word line WL or bit line BL become larger, the time constant becomes greater and the read time become longer. As described above, the length in the bit line BL direction of the memory array 172 of the memory chip 100b is greater than the length in the bit line BL direction of the memory array 172 of the memory chip 100a. Accordingly, the memory chip 100a operates at a higher speed than the memory chip 100b. On the other hand, the memory chip 100b is mainly configured to dispose many memory devices in a limited area, and has a larger memory capacity than the memory chip 100a.

<Cross-Sectional Structure of MEMORY Array>

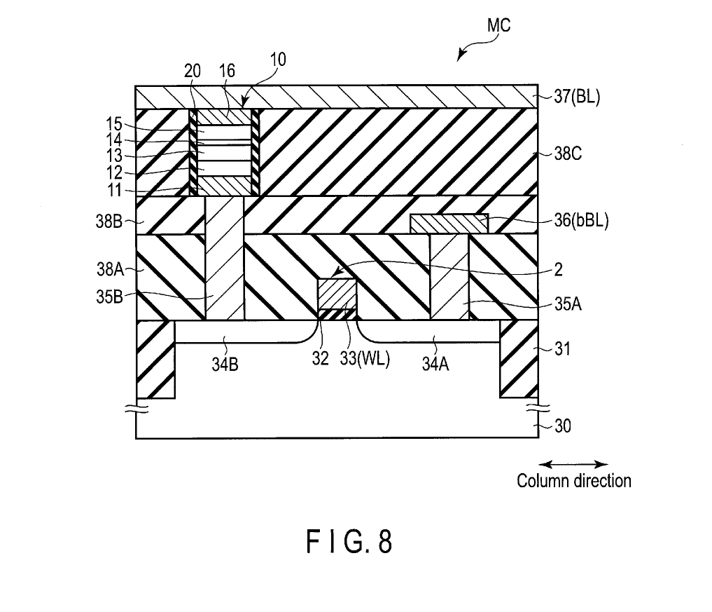

Referring to FIG. 8, a description is given of an example of the structure of the memory cell MC provided in the memory array 172 of the MRAM of the first embodiment. FIG. 8 is a cross-sectional view illustrating the structure of the memory cell MC provided in the memory array 172 of the MRAM of the first embodiment.

As shown in FIG. 8, the memory cell MC is formed in an active area AA of a semiconductor substrate 30. The active area AA is partitioned by an insulation film 31 which is buried in a device isolation region of the semiconductor substrate 30.

The upper end of the MTJ element 10 is connected to a bit line 37 (BL) via an upper electrode 16. In addition, the lower end of the MTJ element 10 is connected to a source/drain diffusion layer 34B of the select transistor 2 via a lower electrode 11 and a contact plug 35B. A source/drain diffusion layer 34A of the select transistor 2 is connected to a bit line 36 (bBL) via a contact plug 35A.

A gate electrode 33 is formed via a gate insulation film 32 on the surface of the active area AA between the source/drain diffusion layer 34A and source/drain diffusion layer 34B. The gate electrode 33 extends in the row direction, and is used as the word line WL.

In the meantime, although the MTJ element 10 is provided immediately above the contact plug 35B, the MTJ element 10 may be disposed at a position (e.g. above the gate electrode 33 of the select transistor 2) displaced from a position immediately above the contact plug 35B, by using an intermediately wiring layer.

FIG. 8 shows the example in which one memory cell MC is provided in one active area AA. However, two memory cells MC, which neighbor in the column direction, may be provided in one active area AA in such a manner that the two memory cells MC share one bit line 36 (bBL) and source/drain diffusion layer 34A. Thereby, the cell size of the memory cell MC can be reduced.

<Layout Example 1 of Synchronous Timing Controller 133>

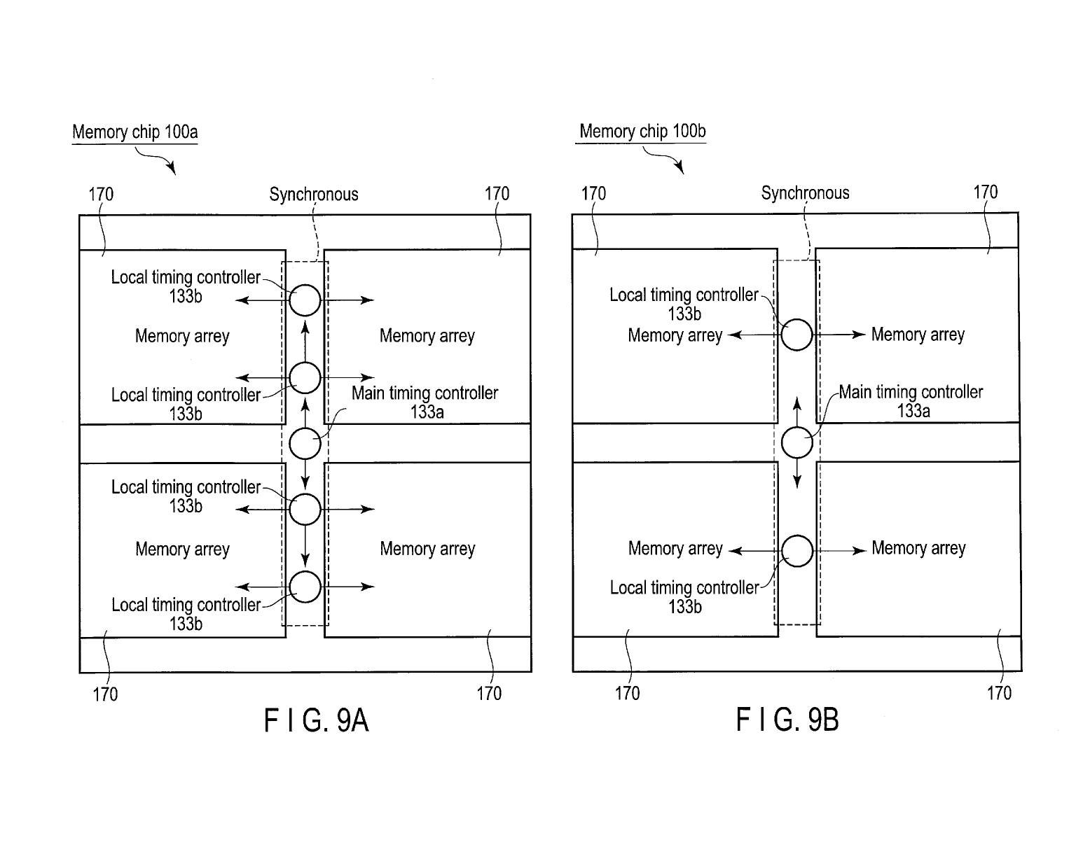

Next, referring to FIG. 9A and FIG. 9B, a schematic description is given of a layout example 1 of the synchronous timing controller 133. FIG. 9A is a plan view illustrating a layout of timing controllers 133 of the memory chip 100a, and FIG. 9B is a plan view illustrating a layout of timing controllers 133 of the memory chip 100b.

As illustrated in FIG. 9A and FIG. 9B, the synchronous timing controller 133 includes a main timing controller 133a and local timing controllers 133b. In the meantime, the main timing controller 133a and local timing controllers 133b operate in sync with an external clock.

As shown in FIG. 9A and FIG. 9B, the main timing controller 133a is disposed at the center of each memory chip 100, and the local timing controllers 133b are arranged near side surfaces of memory arrays 170 and in the vicinity of the sense amplifier.

In addition, the local timing controller 133b does not use the external clock for the memory array 170.

<Layout Example 2 of Synchronous Timing Controller 133>

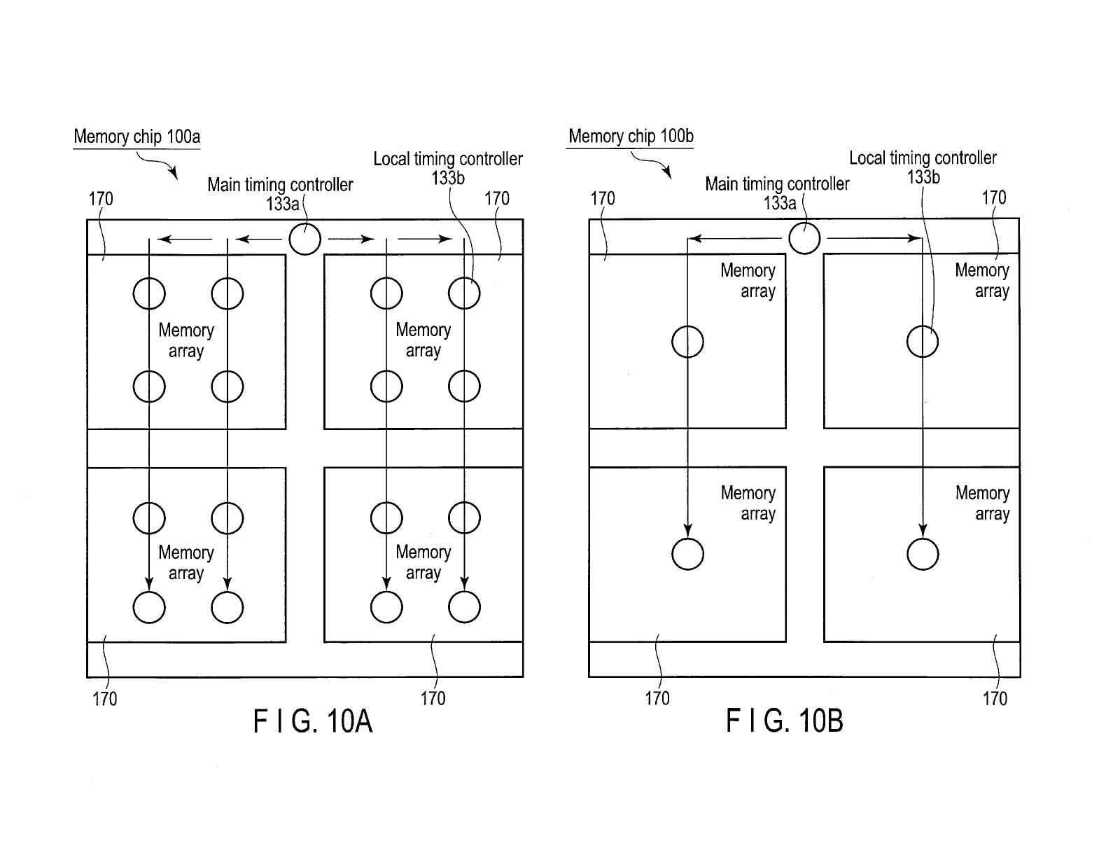

Next, referring to FIG. 10A and FIG. 10B, a schematic description is given of a layout example 2 of the synchronous timing controller 133. FIG. 10A is a plan view illustrating a layout of timing controllers 133 of the memory chip 100a, and FIG. 10B is a plan view illustrating a layout of timing controllers 133 of the memory chip 100b.

As illustrated in FIG. 10A and FIG. 10B, the synchronous timing controller 133 includes a main timing controller 133a and local timing controllers 133b.

As shown in FIG. 10A and FIG. 10B, the main timing controller 133a is disposed at a center of an end portion of each memory chip 100, and the local timing controllers 133b are disposed in the memory arrays 170 and in the vicinity of the sense amplifier.

<Example of Basic Operation of Memory Controller and Memory Chip>

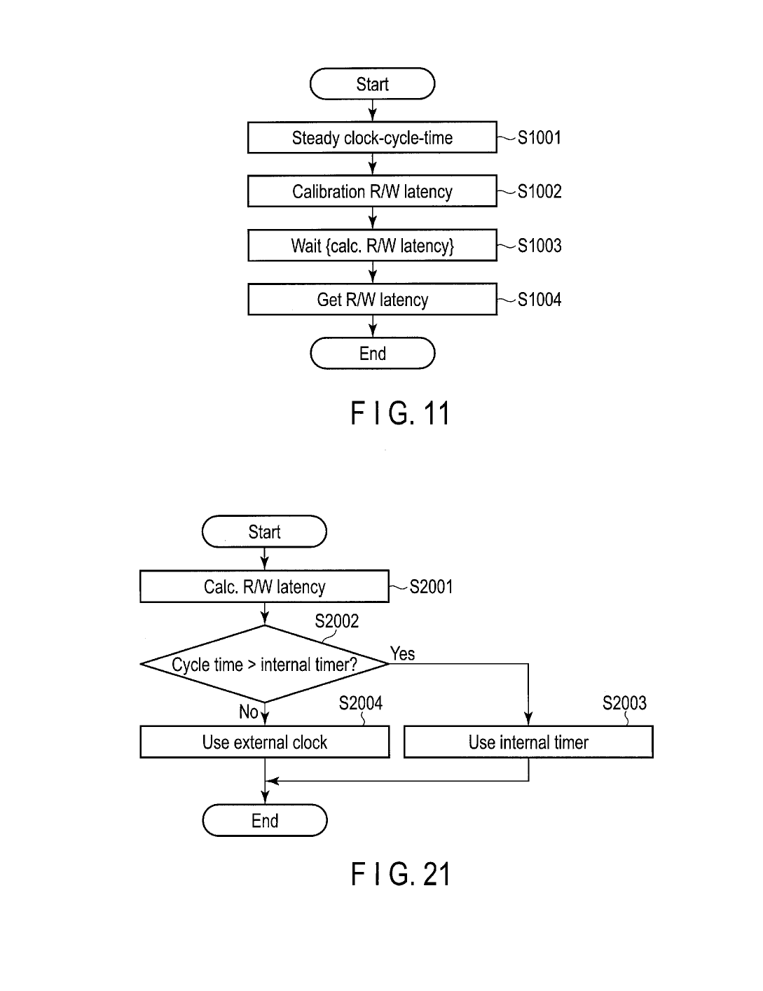

Next, referring to FIG. 11, a description is given of a basic operation of the memory controller 200 and memory chip 100 according to the first embodiment. FIG. 11 is a flowchart illustrating a basic operation when the memory chip 100 derives latency by itself at a power-on time of the memory chip 100 or at a power-down restoration time.

[Step S1001] Steady Clock-Cycle-Time

In step S1001, the memory controller 200 executes operation setting (program) for the mode register 122 of the memory chip 100. To be more specific, the memory controller 200 issues a mode register write command to the memory chip 100.

[Step S1002] Calibration R/W Latency

The memory controller 200 sets a minimum clock number, which is necessary for operation frequency detection of the memory chip 100, for the clock buffer 110.

[Step S1003] Wait{Calc. R/W Latency}

Next, in step S1003, based on the operation frequency set in the clock buffer 110, the memory chip 100 calculates a clock latency corresponding to read/write, by the clock comparator 131 and latency decoder 132, and sets the clock latency in the status register 123 for notification.

[Step S1004] Get R/W Latency

In step S1004, the memory controller 200 issues a mode register read command to the memory chip 100, thereby acquiring a read latency or write latency from the status register 123 of each memory chip 100. In this manner, the memory controller 200 can acquire the read timing and write timing for each memory chip 100.

<Operation Example 1 of Read and Write>

An active command in this operation example 1 is issued by the memory controller 200 before control of read or write. The command interval from “active” to read or write is defined by a clock number nRCD which is calculated by the memory chip 100 in accordance with the operation environment (mainly the clock frequency). Before issuing an active command to a bank which is set in “active”, precharge has to be executed for the bank. The command interval from precharge to “active” is defined by tRP.

After the memory controller 200 issues a read command in this operation example 1, data is output from the memory chip 100 after read latency.

After the memory controller 200 issues a write command in this operation example 1, data is written in the memory chip 100 after write latency. The command interval from write to precharge is defined by a clock number nWR which is calculated by the memory chip 100 in accordance with the operation environment (mainly the clock frequency).

The memory controller 200 issues a precharge command in this operation example 1 after control of read or write. The command interval from precharge to “active” is defined by tRP.

The mode register read command in the operation example 1 is a command for the memory chip 100 to read out, from the status register 123, the clock number of the necessary command interval in accordance with the operation state (clock frequency or temperature).

The mode register write command MRh in the operation example 1 is a command for the memory controller 200 to prompt the memory chip 100 to execute calculation of a special command interval (Special Latency) of, e.g. the mode register read command.

In addition, the mode register write command MRi is a command for the controller to prompt the memory chip to issue when transitioning to a slow operation at a frequency lower than a specified frequency.

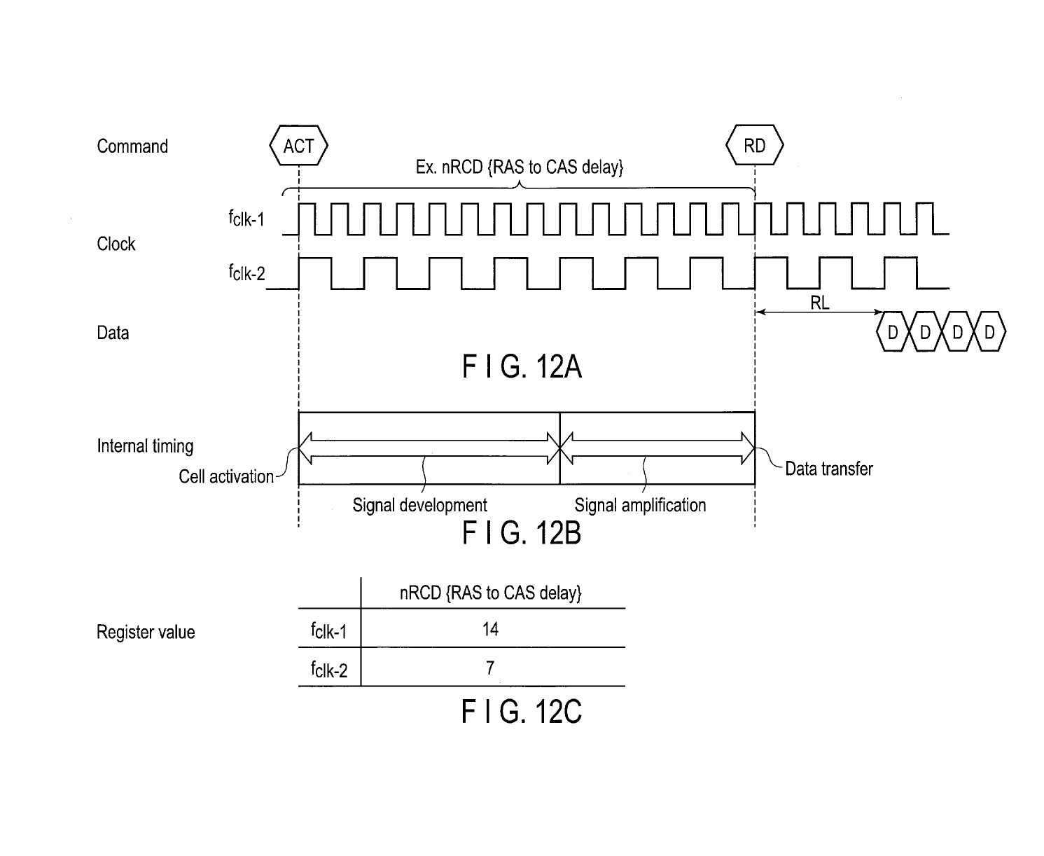

Next, referring to FIG. 12A, FIG. 12B and FIG. 12C, a schematic description is given of the read operation of the memory chip 100 according to the present embodiment.

FIG. 12A is a timing chart relating to the read operation of the memory chip 100 according to the embodiment, FIG. 12B is a timing chart illustrating an internal timing, and FIG. 12C is a view illustrating a relationship between a clock frequency to the memory chip and nRCD.

As illustrated in FIG. 12A, when the memory controller 200 reads out data from the memory chip 100, the memory controller 200 issues an active command, together with a row address, to the memory chip 100, and then issues a read command, together with a column address. Thereby, after the passing of a predetermined time (RL), the memory controller 200 can read out data from the memory chip 100.

As illustrated in FIG. 12A, FIG. 12B and FIG. 12C, it is necessary to wait by a predetermined clock number (nRCD: RAS to CAS Delay) from when the active command is input to the memory chip 100 to when the read command is issued to the memory chip 100. Then, this nRCD is derived by the clock comparator 131, and is stored in the status register 123.

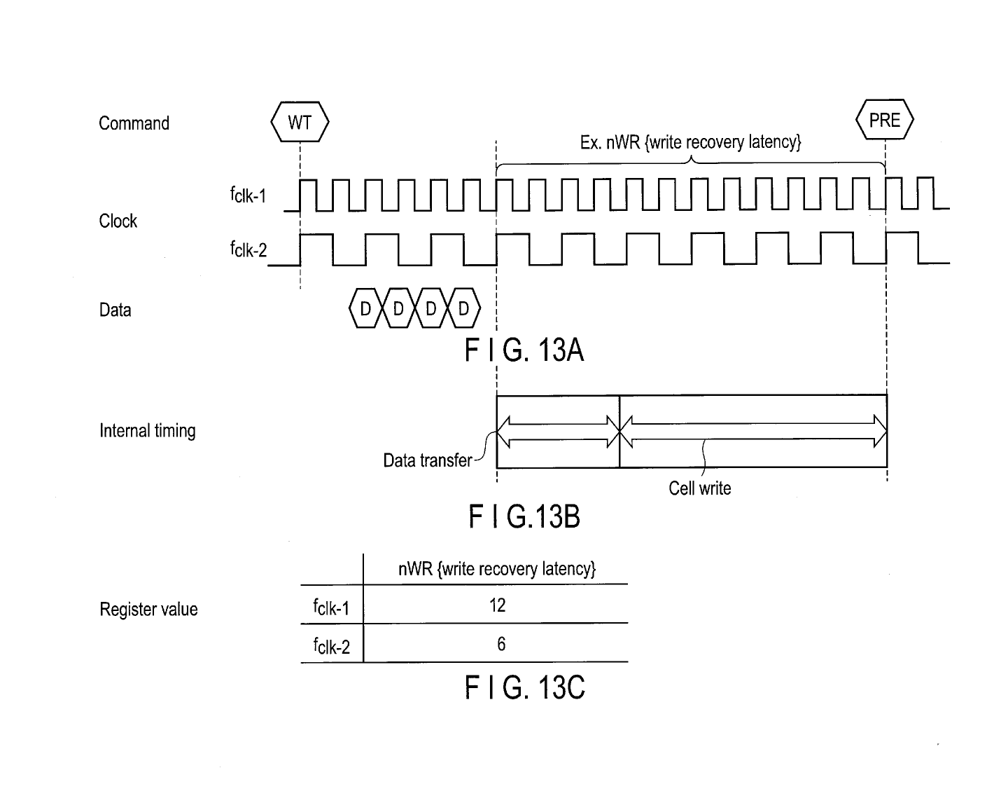

Next, referring to FIG. 13A, FIG. 13B and FIG. 13C, a schematic description is given of the write operation of the memory chip 100 according to the present embodiment.

FIG. 13A is a timing chart relating to the write operation of the memory chip 100 according to the embodiment, FIG. 13B is a timing chart illustrating an internal timing, and FIG. 13C is a view illustrating a relationship between a clock frequency to the memory chip and nWR (Write Recovery Latency).

As illustrated in FIG. 13A and FIG. 13B, when the memory controller 200 writes data in the memory chip 100, the memory controller 200 issues a write command to the memory chip 100 and then supplies write data. Thereby, after the passing of a predetermined time (nWR), data is written in the memory chip 100.

As illustrated in FIG. 13A, FIG. 13B and FIG. 13C, it is necessary to wait by a predetermined clock number (nWR) from when data is input to the memory chip 100 to when data write is completed in the memory chip 100 and the memory controller 200 issues a precharge command. Then, this nWR is derived by the clock comparator 131, and is stored in the status register 123.

As described above, in the operation example 1, the read is executed at a timing of the active command, and the write is executed at a timing of the write command.

<Operation Example 2 of Read and Write>

An active command in this operation example 2 is issued by the memory controller 200 before control of read or write. The command interval from “active” to read or write is defined by a clock number nRCD which is calculated by the memory chip in accordance with the operation environment (mainly the clock frequency). Before issuing an active command to a bank which is set in “active”, precharge has to be executed for the bank. The command interval from precharge to “active” is defined by nRP.

After the memory controller 200 issues a read command in this operation example 2, data is output from the memory chip 100 after read latency.

After the memory controller 200 issues a write command in this operation example 2, data is written in the memory chip 100 after write latency.

A precharge command in the operation example 2 is issued after control of read or write. The command interval from precharge to “active” is defined by a clock number nRP which is calculated by the memory chip in accordance with the operation environment (mainly the clock frequency).

As described above, in the operation example 2, the read is executed at a timing of the active command, and the write is executed at a timing of the precharge command.

<Operation Example 3 of Read and Write>

An active command in this operation example 3 is issued by the memory controller 200 before control of read or write. The command interval from “active” to read or write is defined by a clock number tRCD.

Before issuing an active command to a bank which is set in “active”, precharge has to be executed for the bank. The command interval from precharge to “active” is defined by tRP.

After the memory controller 200 issues a read command in this operation example 3, data is output from the memory chip 100 after read latency. The clock interval from “read” to data is defined by a clock number nRL which is calculated by the memory chip in accordance with the operation environment (mainly the clock frequency).

After the memory controller 200 issues a write command in this operation example 3, data is written in the memory chip 100 after write latency. The clock interval from “write” to data is defined by a clock number nWL which is calculated by the memory chip in accordance with the operation environment (mainly the clock frequency).

A precharge command in the operation example 3 is issued after control of read or write. The command interval from precharge to “active” is defined by tRP.

As described above, in the operation example 3, the read is executed at a timing of the read command, and the write is executed at a timing of the write command.

Although the read operation and write operation for the memory chip 100 have been described above, the described operations are merely examples, and are not necessarily limited to these examples.

<Operation Example 4 of Read and Write>

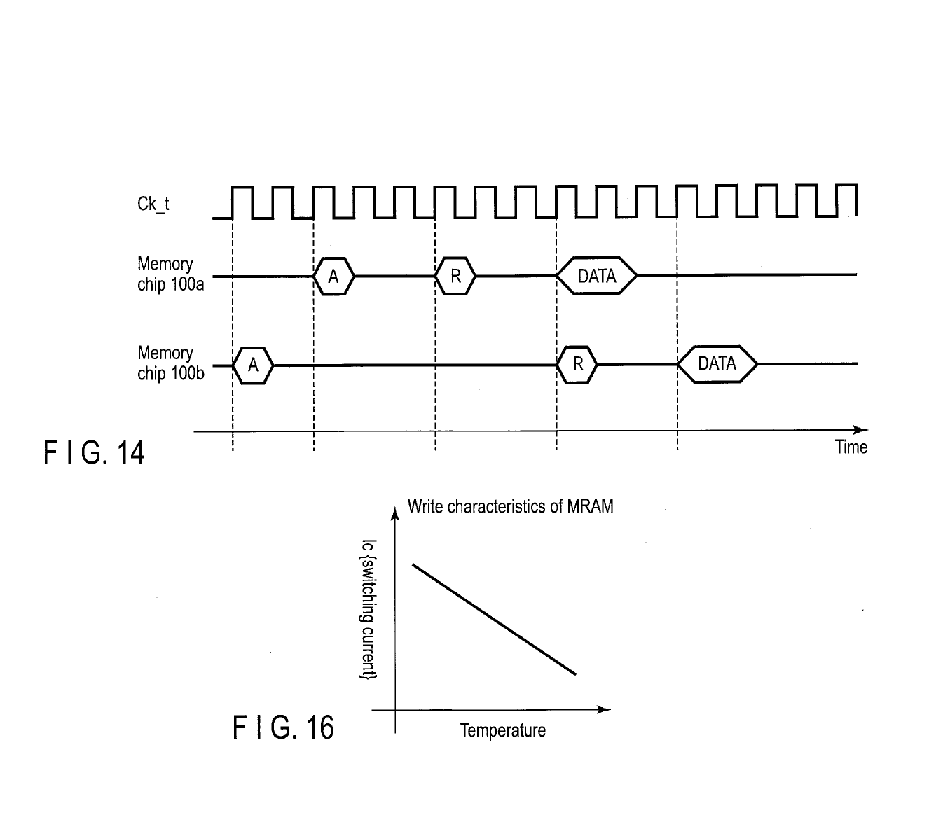

Next, referring to FIG. 14, a description is given of an example of exchange of commands and data between the memory controller 200, and the memory chip 100a and memory chip 100b. FIG. 14 is a timing chart illustrating a timing between the memory controller 200, and the memory chip 100a and memory chip 100b.

For example, the memory chip 100a and memory chip 100b have different read latencies or write latencies.

FIG. 14 illustrates the read operation. As shown in FIG. 14, when the memory controller 200 reads out data from the memory chip 100a and memory chip 100b, the memory controller 200 issues Activate commands to the respective memory chips. In the meantime, when the memory controller 200 issue the Activate commands, the memory controller 200 also issues row addresses. In the respective memory chips, the latency tRCD until data read-out to the row data buffer is different.

As described above, the memory controller 200 can read out the latency from each memory chip 100. For example, it is assumed that in the memory chip 100a, the time from the reception of the active command to the activation of the memory cell is 3 clocks, and that in the memory chip 100b, the time from the reception of the active command to the activation of the memory cell is 6 clocks. Thus, the memory controller 200 issues the active commands at the timing as shown in FIG. 14, and then issues read commands. Incidentally, the memory controller 200 issues column addresses at the same time as issuing the read commands. Thereby, after the passing of a predetermined time, data is output from the memory chip 100.

The read operation has been described by way of example. At the time of the write operation, too, the memory controller 200 issues various commands to each memory chip 100, based on the information acquired from the status register 123.

<Re: Variation in Latency>

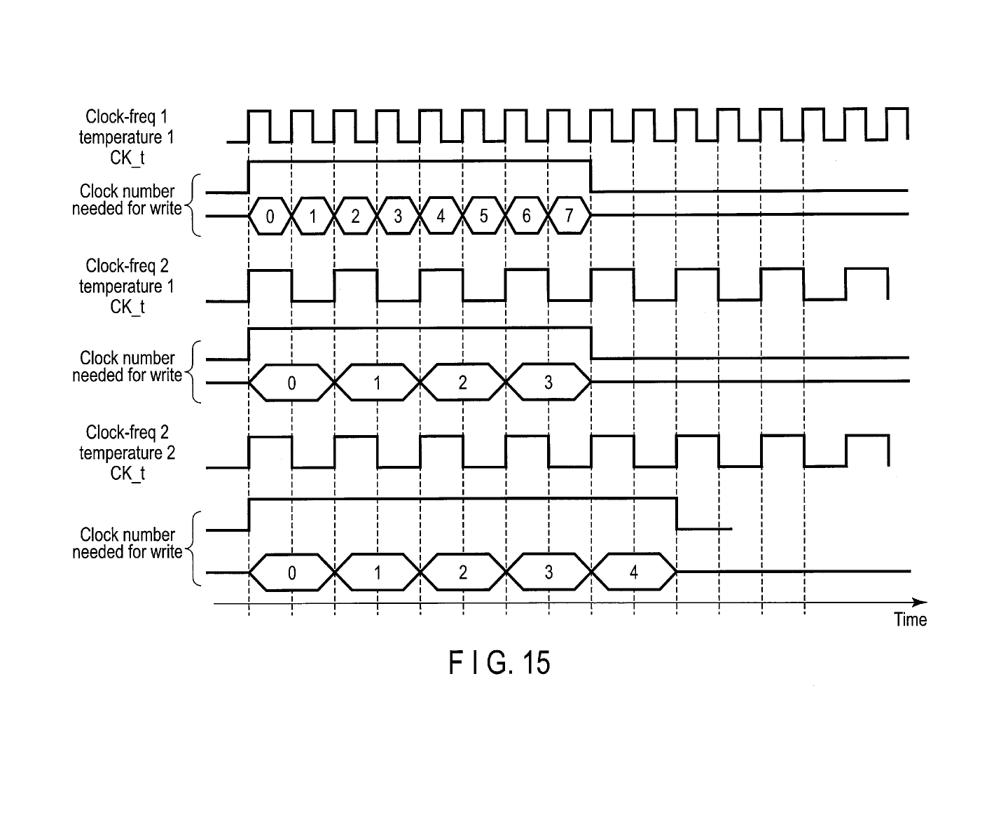

Next, referring to FIG. 15 and FIG. 16, a description is given of the variation in latency when the frequency of the external clock or the temperature of the memory chip 100a has varied. FIG. 15 is a view illustrating the variation in latency when the frequency of the external clock or the temperature of the memory chip 100a has varied. FIG. 16 is a graph illustrating temperature characteristics of the MRAM.

For the purpose of simplicity, a description is given of the variation in latency when the frequency of the external clock has varied in the memory chip 100 or the temperature of the memory chip 100 has varied.

As illustrated in FIG. 15, when the frequency of the external clock is in a frequency state 1 and the state of the temperature is a temperature state 1, the memory chip 100a determines that write can be executed with 8 clocks.

In addition, when the frequency of the external clock is in a frequency state 2 (frequency state 1>frequency state 2) and the state of the temperature is the temperature state 1, the memory chip 100a determines that write can be executed with 4 clocks.

Furthermore, when the frequency of the external clock is in the frequency state 2 (frequency state 1>frequency state 2) and the state of the temperature is a temperature state 2 (temperature state 1<temperature state 2), the memory chip 100a determines that write can be executed with 5 clocks.

As illustrated in FIG. 16, since the characteristics of the MRAM vary due to the ambient temperature, the clock number, etc. necessary for write may vary, as described above.

### Advantageous Effects of the First Embodiment

In the above-described first embodiment, the memory chip 100 derives the read/write latency (interval) based on the operation of the memory chip 100. The memory controller 200 reads the read/write latency from the memory chip 100, and issues the command to the memory chip 100, based on the latency. The operation state described here refers to the frequency of the clock that is supplied from the memory controller 200 to the memory chip 100, the ambient temperature, etc.

In addition, with the above-described structure, even in the case where a plurality of memory chips 100 with different specifications are provided, each memory chip 100 individually derives the latency in accordance with the variations of, for example, the frequency of the external clock, the temperature of the memory chip, and the voltage supplied to the memory chip. Therefore, the memory controller 200 can easily manage and control the plural memory chips 100.

In the meantime, in the DRAM interface, the memory controller statically executes operation setting of the memory chip. However, such a scheme is adopted that some command intervals (internal device read time, internal device write time) are dynamically determined by the memory chip side, and the memory controller makes use of these latencies. It is thus possible to improve the scalability in the difference of capabilities between plural memory chips or in the difference of nonvolatility technologies. In other words, even if plural kinds of memory chips are provided, since the memory chip itself derives a proper latency, the memory controller can easily control the plural kinds of memory chips.

### Second Embodiment

Next, a second embodiment is described. The basic structures and basic operations of a memory controller and a memory chip according to the second embodiment are the same as those of the memory controller and memory chip according to the above-described first embodiment. Thus, descriptions are omitted as regards the matters described in the first embodiment and matters which can be easily guessed from the first embodiment.

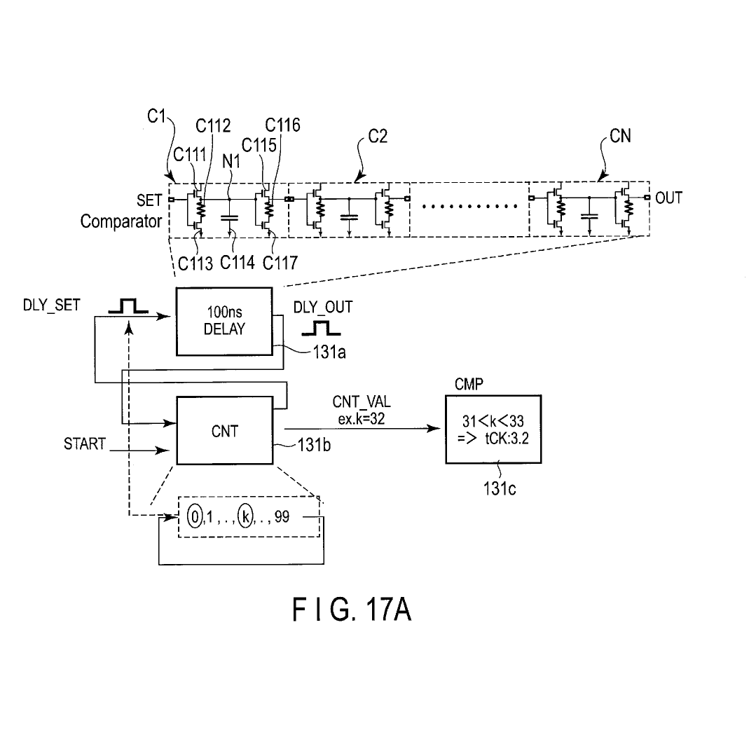

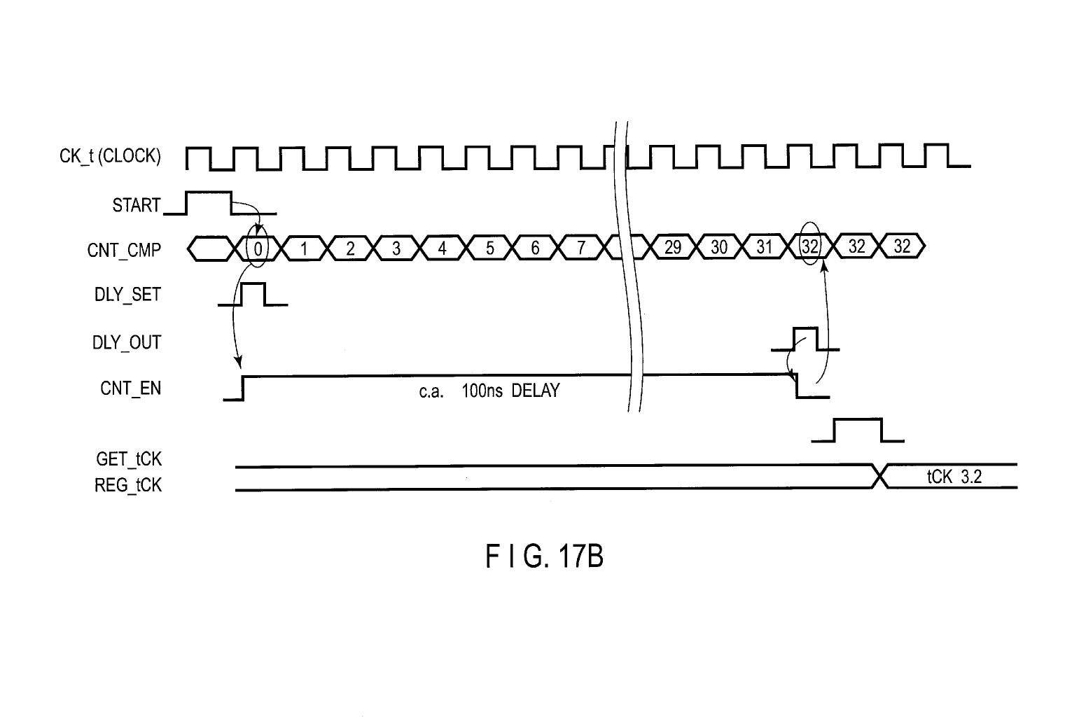

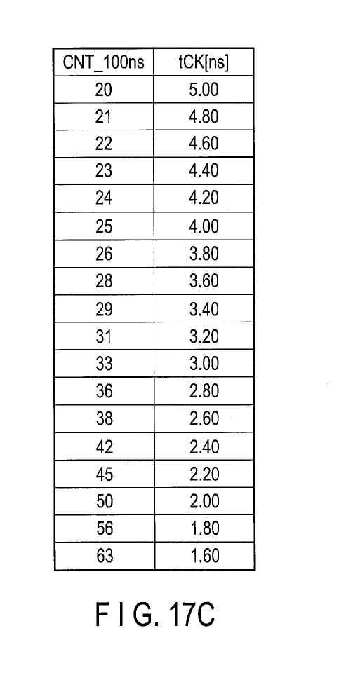

Referring to FIG. 17A, FIG. 17B and FIG. 17C, a concrete structure of the clock comparator 131 is described. FIG. 17A is a circuit diagram illustrating a concrete structure of the clock comparator 131. FIG. 17B is a timing chart relating to the operation of the clock comparator 131. FIG. 17C is a view illustrating a relationship between a count number and time.

The clock comparator 131 is a circuit which detects the external clock frequency. The clock comparator 131 internally includes a delay circuit of about 10 to 100 ns, and has such a circuit structure as to detect, with a precision of several times to several tens of times, that the external clock is 2.5 ns to 3 ns.

As illustrated in FIG. 17A, the clock comparator 131 includes a timer 131a, a counter 131b, and a comparison module 131c.

The timer 131a is a delay circuit of about 10 to 100 ns. In this embodiment, it is assumed that the timer 131 is a delay circuit of 100 ns.

The counter 131b continues to count up the external clock for a predetermined period (e.g. 100 ns) which is set in the timer 131a. If the counting is finished, the counter 131b transfers a count value, which is the result of counting, to the comparison module 131c.

Using the count value transfered from the counter 131b, the comparison module 131c derives a time tCK [ns] of the external clock by referring to an internally set table.

In the meantime, the timer 131a includes N (N is an integer of 2 or more) delay modules. Incidentally, when delay modules C1 to CN are not discriminated, the delay modules are simply referred to as “delay module”. The delay module includes a PMOS transistor C111, a resistor element C112, an NMOS transistor C113, a capacitor C114, a PMOS transistor C115, a resistor element C116, and an NMOS transistor C117.

The counter 131b is connected to a gate electrode of the PMOS transistor C111. A power supply is connected to one end of the current path of the PMOS transistor C111, and a node N1 is connected to the other end of the current path.

The counter 131b is connected to a gate electrode of the NMOS transistor C113. A ground potential is connected to one end of the current path of the NMOS transistor C113, and the other end of the resistor element C112 is connected to the other end of the current path.

The node N1 is connected to one end of the capacitor C114, and a ground potential is connected to the other end of the capacitor C114.

The other end of the current path of the PMOS transistor C111 is connected to a gate electrode of the PMOS transistor C115. A power supply is connected to one end of the current path of the PMOS transistor C115, and one end of the resistor element 116 is connected to the other end of the current path.

The other end of the current path of the PMOS transistor C111 is connected to a gate electrode of the NMOS transistor C117. A ground potential is connected to one end of the current path of the NMOS transistor C117, and the other end of the resistor element 116 is connected to the other end of the current path.

Next, referring to FIG. 17B and FIG. 17C, the basic operation of the clock comparator 131 according to this embodiment is described.

As illustrated in FIG. 17B, for example, a mode register write command MRhn input timing is START. In accordance with this, DLY_SET is supplied from the counter 131b to the timer 131a. The timer 131a executes a delay of 100 ns from the supply of DLY_SET (CNT_EN). Then, for example, if a DLY_OUT signal is output from the delay module CN of the timer 131a, the counter 131a supplies a result CNT_VAL (e.g. k=32) of a counter value CNT_CMP to the comparison module 131c. The comparison module 131c derives a value of tCK of a clock frequency (GET_tCK). To be more specific, the comparison module 131c refers to the table shown in FIG. 17C. Values are discretely set in this table and, for example, the value of tCK corresponding to k=32 is not set. However, since k=32 is a value between k=31 and k=33, the comparison module 131c outputs, for example, tCK of k=31 with a greater tCK, as the value of k=32. Thereby, a latency corresponding to tCK=3.2 ns is set in the status register 123 (REG_tCK).

### Third Embodiment

Next, a third embodiment is described. The basic structures and basic operations of a memory controller and a memory chip according to the third embodiment are the same as those of the memory controller and memory chip according to the above-described first embodiment. Thus, descriptions are omitted as regards the matters described in the first embodiment and matters which can be easily guessed from the first embodiment.

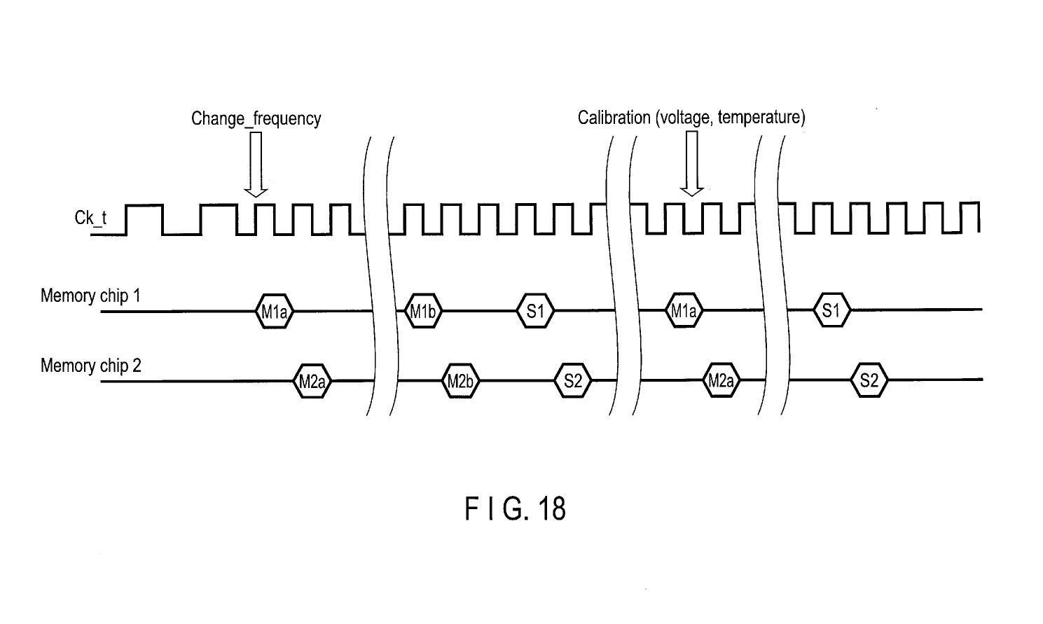

Next, referring to FIG. 18, a description is given of an operation in a case where conditions, such as the frequency of the external clock of the memory controller 200, are varied. FIG. 18 is a timing chart illustrating an example of exchange of commands and data between the memory controller 200 and the memory chip 100a and memory chip 100b.

For example, the memory chip 100a and memory chip 100b have different read latencies or write latencies.

The memory controller 200 issues a command M1a (mode register write command) to the memory chip 100a, thus being able to re-set the latency of the memory chip 100a in order to correct a temperature variation, a voltage variation, etc. Similarly, the memory controller 200 issues a command M2a (mode register write command) to the memory chip 100b, thus being able to re-set the latency of the memory chip 100b in order to correct a temperature variation, a voltage variation, etc. In addition, the memory controller 200 issues a command M1b to the memory chip 100a, thus being able to execute various settings in the mode register 122 of the memory chip 100a. The memory controller 200 issues a command M2b to the memory chip 100b, thus being able to execute various settings in the mode register 122 of the memory chip 100b. Furthermore, the memory controller 200 issues a command S1 (mode register read command) to the memory chip 100a, thus being able to read out the latency from the status register 123 of the memory chip 100a. The memory controller 200 issues a command S2 (mode register read command) to the memory chip 100b, thus being able to read out the latency from the status register 123 of the memory chip 100b.

As illustrated in FIG. 18, the memory controller 200 issues the commands M1a and M2a to the respective memory chips 100a in order to make the memory chips to re-calculate the latencies of the memory chips 100a when the frequency of the clock is varied. Upon receiving the command M1a or M2a, the memory chip 100a starts calculation of the latency.

Then, in order to execute a read or write operation, the memory controller 200 issues the command M1b or command M2b to each memory chip 100a. Upon receiving the command M1b or M2b, the memory chip 100a changes the setting of the mode register 122.

The memory controller 200 issues the command S1 or command S2 to each memory chip 100a in order to acquire latency information from each memory chip 100a. Upon receiving the command S1 or S2, the memory chip 100a supplies information of the status register 123 to the memory controller 200.

In addition, the memory controller 200 issues the commands M1a and M2a to the respective memory chips 100a, in order to cause the memory chips to re-calculate the latencies of the memory chips 100a when the temperature (the temperature of the memory controller 200 or memory chip 100a) or the voltage (the voltage of the memory controller 200 or memory chip 100a) has varied. Upon receiving the command M1a or M2a, the memory chip 100a starts calculation of the latency.

In this manner, the memory chip 100a according to the present embodiment can execute a flexible frequency change since the memory chip 100a itself calculates the latency, and the latency setting relating to cell characteristics can be entrusted to the calculation in the memory chip 100a.

### Fourth Embodiment

Next, a fourth embodiment is described. The basic structures and basic operations of a memory controller and a memory chip according to the fourth embodiment are the same as those of the memory controller and memory chip according to the above-described first embodiment. Thus, descriptions are omitted as regards the matters described in the first embodiment and matters which can be easily guessed from the first embodiment.

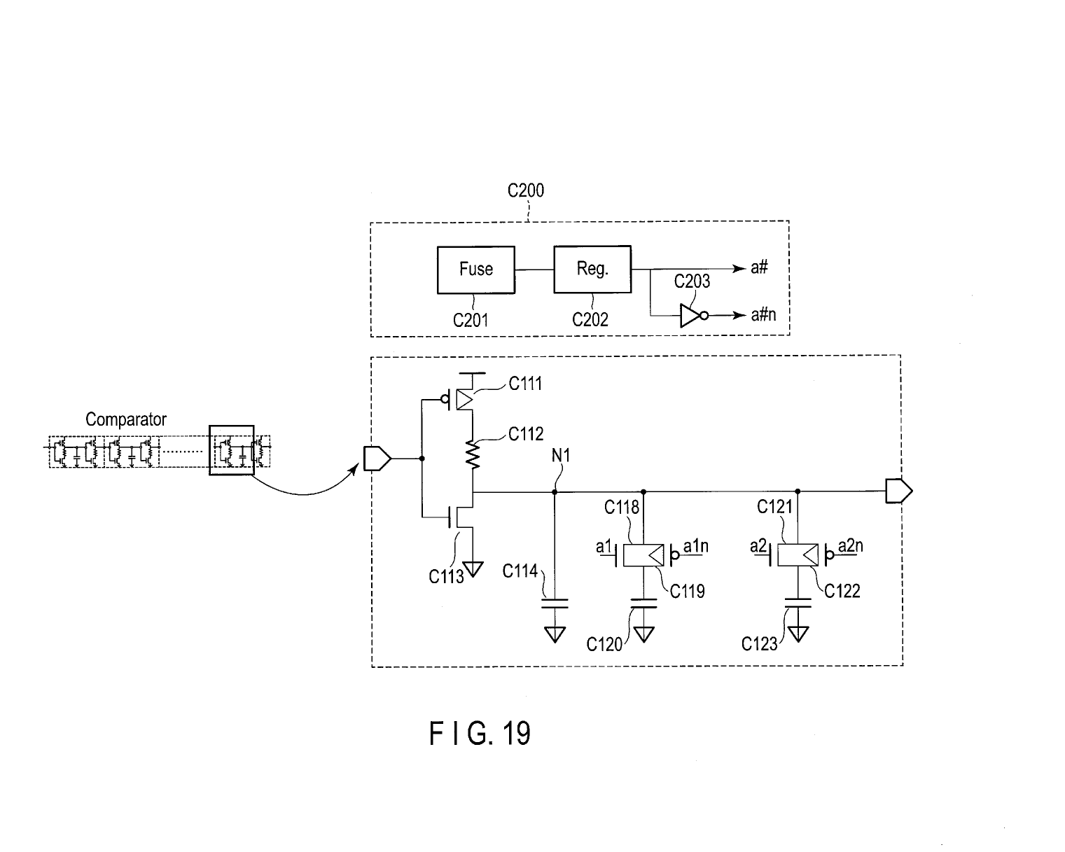

Referring to FIG. 19, a schematic description is given of the structure of a clock comparator 131 according to the present embodiment. FIG. 19 is a circuit diagram illustrating a basic structure of the clock comparator 131 according to the present embodiment.

As illustrated in FIG. 19, the clock comparator (frequency detection device) 131 in the memory chip 100 according to the present embodiment has such a mechanism as to be able to regulate a delay in a shipping test.

The clock comparator 131 further includes a plurality of regulators C200. The regulator C200 includes a laser fuse or ROM fuse C201, a register C202, and an inverter C203.

In addition, the delay circuit includes an NMOS transistor C118, a PMOS transistor C119, a capacitor C120, an NMOS transistor C121, a PMOS transistor C122, and a capacitor C123.

An output signal a1 of the register C202 is input to the gate electrode of the NMOS transistor C118, one end of the current path of the NMOS transistor C118 is connected to a node N1, and the other end of the current path is connected to one end of the capacitor C120. An output signal a1n of the inverter C203 is input to the gate electrode of the PMOS transistor C119, one end of the current path of the PMOS transistor C119 is connected to the node N1, and the other end of the current path is connected to the one end of the capacitor C120. The other end of the capacitor C120 is connected to a ground potential.

In addition, an output signal a2 of the register C202 is input to the gate electrode of the NMOS transistor C121, one end of the current path of the NMOS transistor C121 is connected to the node N1, and the other end of the current path is connected to one end of the capacitor C123. An output signal a2n of the inverter C203 is input to the gate electrode of the PMOS transistor C122, one end of the current path of the PMOS transistor C122 is connected to the node N1, and the other end of the current path is connected to the one end of the capacitor C123. The other end of the capacitor C123 is connected to a ground potential.

Thereby, in a shipping test, it is possible to confirm a frequency detection level, and to regulate a delay of the frequency detection level where necessary. Thereby, the chip yield can be increased.

### Fifth Embodiment

Next, a fifth embodiment is described. The basic structures and basic operations of a memory controller and a memory chip according to the fifth embodiment are the same as those of the memory controller and memory chip according to the above-described first embodiment. Thus, descriptions are omitted as regards the matters described in the first embodiment and matters which can be easily guessed from the first embodiment.

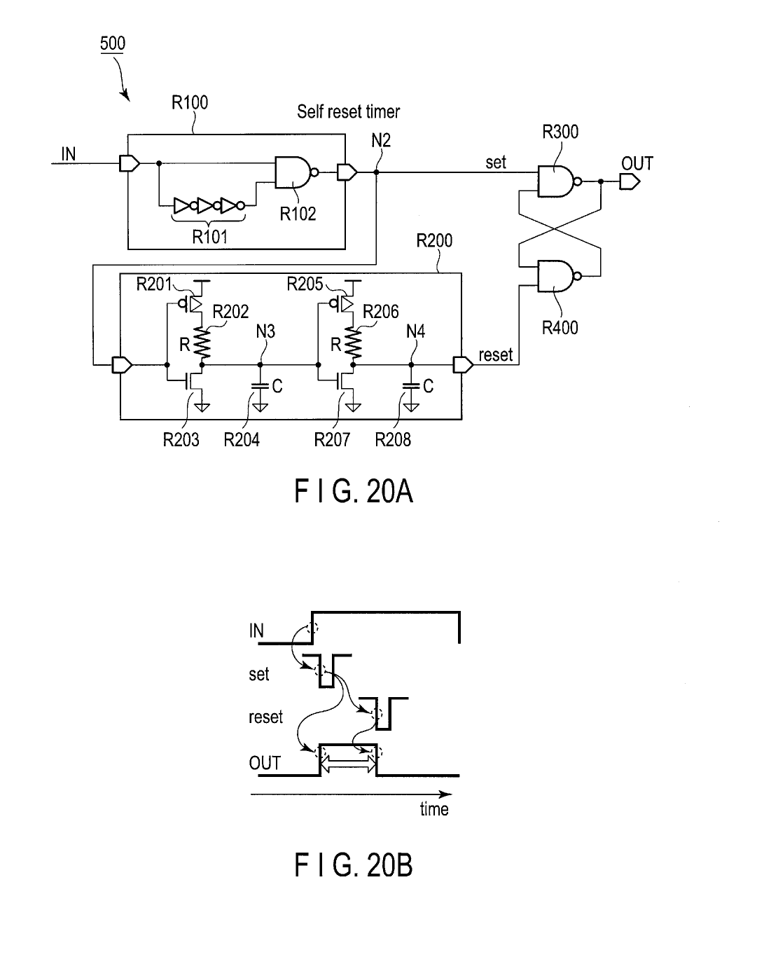

Next, referring to FIG. 20A and FIG. 20B, a self reset timer (asynchronous circuit) 500 according to the present embodiment is described. FIG. 20A is a circuit diagram illustrating a basic structure of the self reset timer 500 according to the embodiment, and FIG. 20B is a timing chart illustrating a basic operation of the self reset timer 500 according to the embodiment. When the clock cycle is several to several-ten ns, control is configured to be executed with a high-precision external clock. When the clock cycle is very slow, control is executed by the self reset timer 500 so that a write current and a read current are not applied to the memory cells of the MRAM for a predetermined time or more. A multiplexer is provided to effect switching to an asynchronous operation when the upper limit of the clock comparator 131 has been exceeded.

As illustrated in FIG. 20A, the self reset timer 500 includes a set circuit R100, a reset circuit R200, a NAND gate R300 and a NAND gate R400.

The set circuit R100 includes a plurality of inverters R101 which receive an input signal, and a NAND gate 8102 having one end which receives the input signal, the other end which receives an output of the inverter R101, and an output terminal which is connected to a node N2.

The reset circuit R200 includes a PMOS transistor R201, a resistor element R202, an NMOS transistor R203, a capacitor R204, a PMOS transistor R205, a resistor element R206, an NMOS transistor R207, and a capacitor R208.

The gate electrode of the PMOS transistor R201 is connected to the node N2, one end of the current path thereof is connected to a power supply, and the other end of the current path is connected to one end of the resistor element R202.

The gate electrode of the NMOS transistor R203 is connected to the node N2, one end of the current path thereof is connected to a ground potential, and the other end of the current path is connected to the other end of the resistor element R202 and a node N3.

One end of the capacitor R204 is connected to the node N3, and the other end thereof is connected to a ground potential.

The gate electrode of the PMOS transistor R205 is connected to the node N3, one end of the current path thereof is connected to a power supply, and the other end of the current path is connected to one end of the resistor element 8206.

The gate electrode of the NMOS transistor R207 is connected to the node N3, one end of the current path thereof is connected to a ground potential, and the other end of the current path is connected to the other end of the resistor element R206 and a node N4.

One end of the capacitor R208 is connected to the node N4, and the other end thereof is connected to a ground potential.

The NAND gate R300 has one input terminal connected to the node N2, has the other input terminal connected to an output terminal of the NAND gate R400, and has an output terminal connected to an output terminal of the self reset timer 500. In addition, the NAND gate R400 has one input terminal connected to the node N4, and has the other input terminal connected to the output terminal of the NAND gate R300. In this manner, a flip-flop circuit is constituted by the NAND gates 8300 and 8400.

As illustrated in FIG. 20B, if a command, which is synchronized with the external clock, is input to the self reset timer 500, turn-off occurs by the flip-flop circuit after the passing of a predetermined time.

Next, referring to FIG. 21, the operation of the embodiment is schematically described. FIG. 21 is a flowchart illustrating a basic operation of the memory chip 100 using the self reset timer according to the embodiment.

[S2001] Calc. R/W Latency

The memory chip 100 derives a read latency and a write latency, based on the external clock.

[S2002] Cycle Time>Internal Timer?

It is determined whether the cycle time of the external clock exceeds the limit of the self reset timer (internal timer) 500.

[S2003] Use Internal Timer

In step S2002, if the cycle time of the external clock exceeds the limit that is set by the self reset timer (internal timer) 500, the use of the external clock is stopped.

[S2004] Use External Clock

In step S2002, if the cycle time of the external clock does not exceed the limit that is set by the self reset timer (internal timer) 500, the external clock is used.

### Sixth Embodiment

Next, a sixth embodiment is described. The basic structures and basic operations of a memory controller and a memory chip according to the sixth embodiment are the same as those of the memory controller and memory chip according to the above-described first embodiment. Thus, descriptions are omitted as regards the matters described in the first embodiment and matters which can be easily guessed from the first embodiment.

In the meantime, two types of TSV layout are thinkable, namely “Center-PAD type” in which TSVs are arranged on a central area of the memory chip, and “Edge-PAD type” in which TSVs are arranged on an end area of the memory chip. Based on these two types, layout examples of TSVs will be described below. However, these are merely examples, and, for example, TSVs may be provided on a central area and an end area of the memory chip.

### Layout Example 1

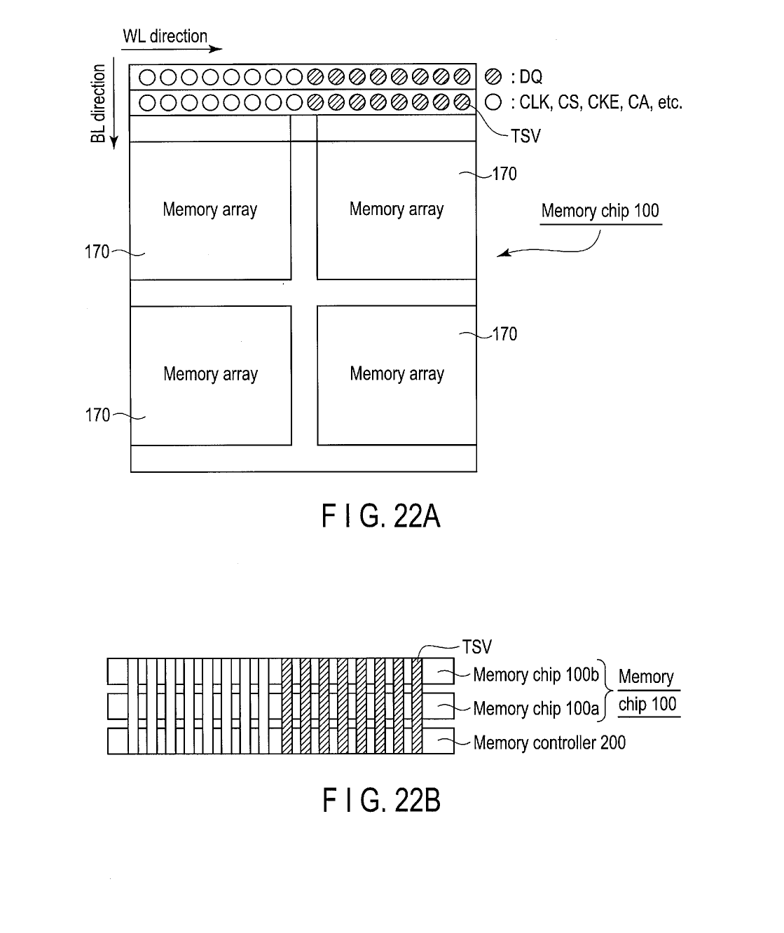

Next, referring to FIG. 22A and FIG. 22B, a layout example 1 of TSVs is described. FIG. 22A is a plan view of a memory chip 100 according to the embodiment, and FIG. 22B is a cross-sectional view of the memory chip 100 and memory controller 200 according to the embodiment.

As illustrated in FIG. 22A and FIG. 22B, a memory controller 200, a memory chip 100a and a memory chip 100b are connected by TSVs. The TSVs are provided along one side in the word line direction of the memory controller 200, memory chip 100a and memory chip 100b.

In the case of the present embodiment, the TSVs are formed in two rows along this side. As illustrated in FIG. 22A and FIG. 22B, TSVs on one side (hatching) are TSVs for DQ, and TSVs on the other side (white) are TSVs for CLK, CS, CKE, CA, etc.

### Layout Example 2

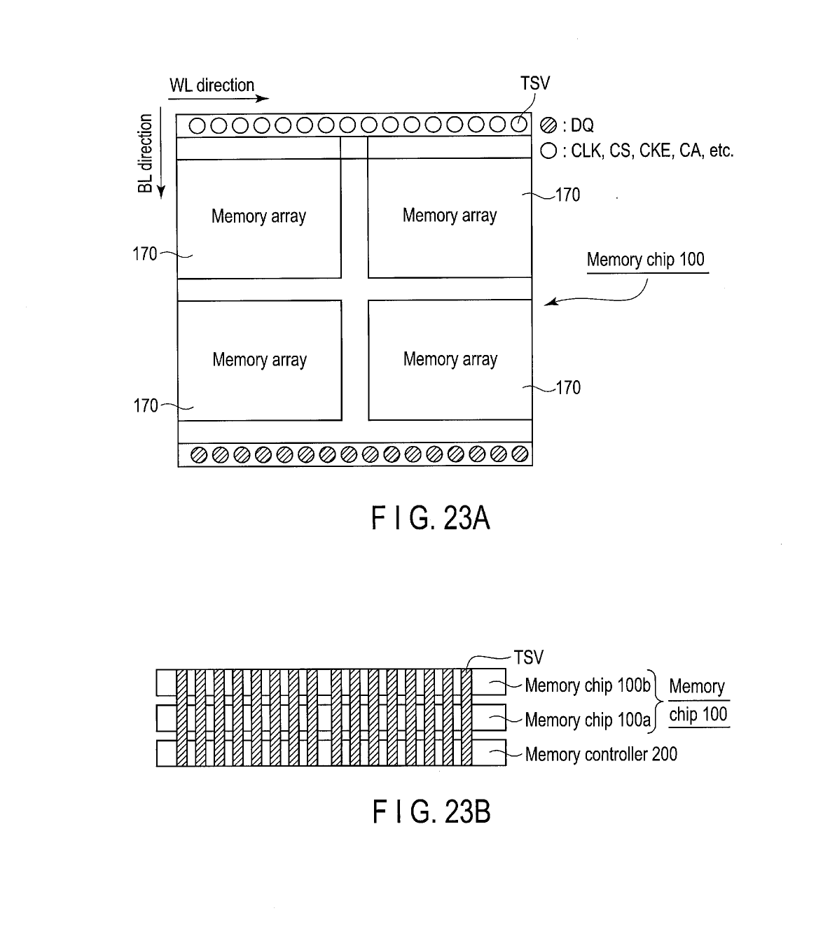

Next, referring to FIG. 23A and FIG. 23B, a layout example 2 of TSVs is described. FIG. 23A is a plan view of a memory chip 100 according to the embodiment, and FIG. 23B is a cross-sectional view of the memory chip 100 and memory controller 200 according to the embodiment.

As illustrated in FIG. 23A and FIG. 23B, a memory controller 200, a memory chip 100a and a memory chip 100b are connected by TSVs. The TSVs are provided along sides in the word line (or the bit line) direction of the memory controller 200, memory chip 100a and memory chip 100b. As illustrated in FIG. 23A and FIG. 23B, TSVs on one side (hatching) are TSVs for DQ, and TSVs on the other side (white) are TSVs for CLK, CS, CKE, CA, etc.

### Layout Example 3

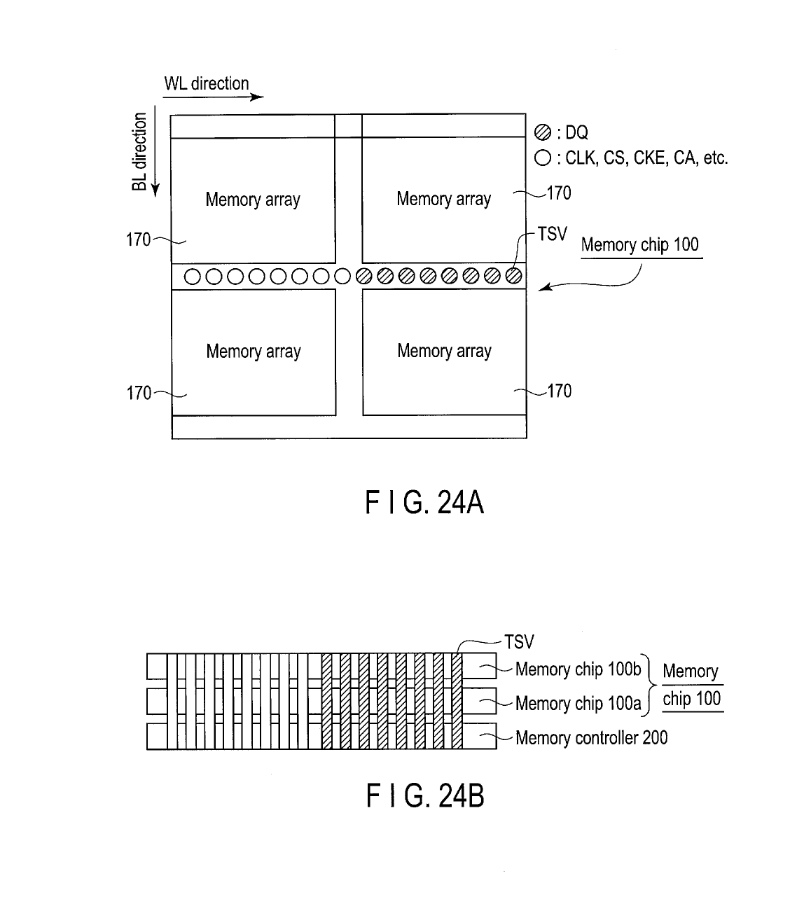

Next, referring to FIG. 24A and FIG. 24B, a layout example 3 of TSVs is described. FIG. 24A is a plan view of a memory chip 100 according to the embodiment, and FIG. 24B is a cross-sectional view of the memory chip 100 and memory controller 200 according to the embodiment.

As illustrated in FIG. 24A and FIG. 24B, a memory controller 200, a memory chip 100a and a memory chip 100b are connected by TSVs. The TSVs are provided on a central area in the word line direction of the memory controller 200, memory chip 100a and memory chip 100b. As illustrated in FIG. 24A and FIG. 24B, TSVs on one side (hatching) are TSVs for DQ, and TSVs on the other side (white) are TSVs for CLK, CS, CKE, CA, etc.

### Layout Example 4

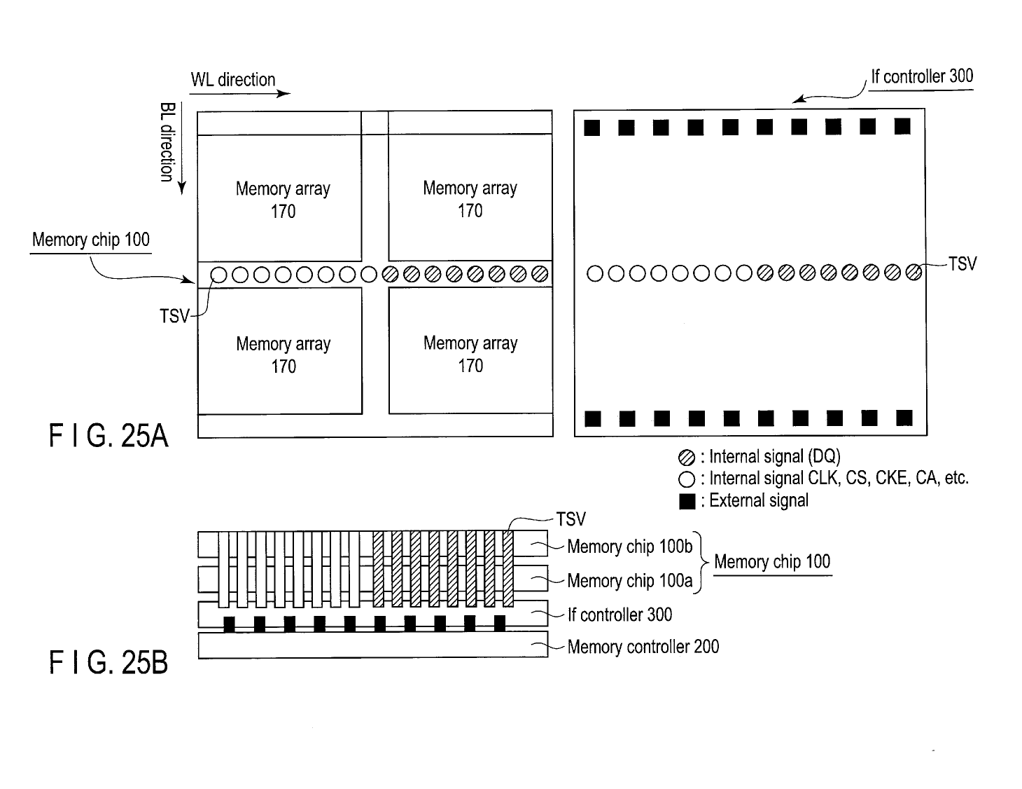

Next, referring to FIG. 25A and FIG. 25B, a layout example 4 of TSVs is described. FIG. 25A is a plan view of a memory chip 100 and an IF controller 300 according to the embodiment, and FIG. 25B is a cross-sectional view of the memory chip 100, IF controller 300 and memory controller 200 according to the embodiment.

As illustrated in FIG. 25A and FIG. 25B, a memory chip 100a, a memory chip 100b and an interface controller 300 are connected by TSVs. In addition, the memory chip 100a and a memory controller 200 are connected via the interface controller 300. Furthermore, the memory controller 200 and interface controller 300 are connected via PADs (see parts in black in the Figures). TSVs for exchanging internal signals are provided on a central area in the word line direction of the memory controller 200, memory chip 100a and memory chip 100b. As illustrated in FIG. 25A and FIG. 25B, TSVs on one side (hatching) are TSVs for DQ, and TSVs on the other side (white) are TSVs for CLK, CS, CKE, CA, etc. Besides, the interface controller 300 is provided with PADs along two sides in parallel to the TSVs in such a manner as not to overlap the TSVs.

### Layout Example 5

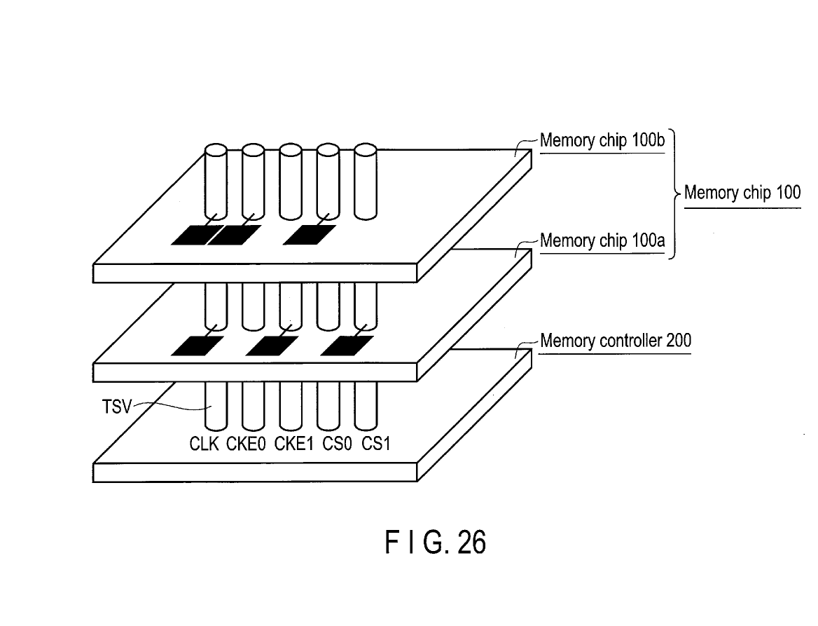

Next, referring to FIG. 26, a layout example 5 of TSVs is described. FIG. 26 is a perspective view of the memory chip 100 and memory controller 200 according to the embodiment.

As illustrated in FIG. 26, a memory controller 200, a memory chip 100a and a memory chip 100b are connected by TSVs. The TSVs are provided along a one-side direction of the memory controller 200, memory chip 100a and memory chip 100b. As shown in FIG. 26, a TSV relating to CLK is commonly connected to the memory chip 100a and memory chip 100b. For example, TSVs relating to CKE0 and CS0 are not connected to the memory chip 100a, but connected to the memory chip 100b. For example, TSVs relating to CKE1 and CS1 are not connected to the memory chip 100b, but connected to the memory chip 100a. In this manner, the TSV, which is commonly connected to the memory chip 100a and memory chip 100b, is referred to as “common wiring”, and the TSV, which is connected to either the memory chip 100a or memory chip 100b, is referred to as “non-common wiring”. Although CLK, CKE and CS alone are illustrated in this example, the embodiment is not limited to this example.

### Layout Example 6

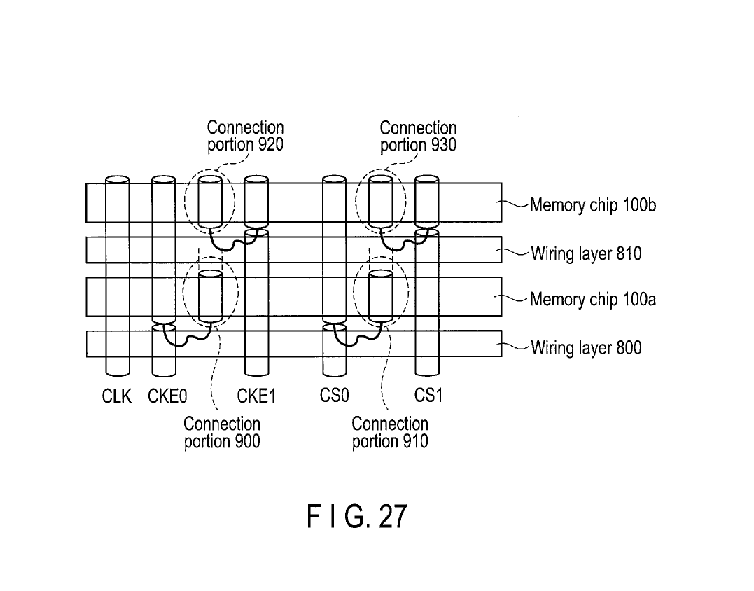

Next, referring to FIG. 27, a layout example 6 of TSVs is described. FIG. 27 is a cross-sectional view of the memory chip 100 and memory controller 200 according to the embodiment.

As illustrated in FIG. 27, a memory controller 200, a memory chip 100a and a memory chip 100b are connected by TSVs. The TSVs are provided along a one-side direction of the memory controller 200, memory chip 100a and memory chip 100b. As shown in FIG. 27, a TSV relating to CLK is commonly connected to the memory chip 100a and memory chip 100b. For example, TSVs relating to CKE0 and CS0 are not connected to the memory chip 100b, but connected to the memory chip 100a at a connection portion 900 and a connection portion 910 in the Figure via a wiring layer 800. For example, TSVs relating to CKE1 and CS1 are not connected to the memory chip 100a, but connected to the memory chip 100b at a connection portion 920 and a connection portion 930 in the Figure via a wiring layer 810. In this manner, the TSV, which is commonly connected to the memory chip 100a and memory chip 100b, is referred to as “common wiring”, and the TSV, which is connected to either the memory chip 100a or memory chip 100b, is referred to as “non-common wiring”. Although CLK, CKE and CS alone are illustrated in this example, the embodiment is not limited to this example.

(Modifications, etc.)

In each of the above-described embodiments, the case has been described that two memory chips 100 having different capabilities are connected to the memory controller 200, but the embodiments are not limited to such examples. A greater number of memory chips 100 may be connected to the memory controller 200, or a plurality of memory chips 100 having the same capabilities may be connected to the memory controller 200.

The memory chip 100 in each of the above-described embodiments may have a command to receive one-step speed-up (down) in order to compensate a difference in frequency precision. In this case, in accordance with the speed regulation command from the memory controller 200, the memory chip 100 varies the frequency detection level, and includes a read/write latency calculation circuit. In this case, the memory controller 200 includes a function of requesting one-step speed-up/down in order to correct and use the frequency detection of the memory chip 100a.

Each of the above-described embodiments illustrates the structure using TSVs. Alternatively, each embodiment may have a package-on-package (POP)-type structure.

In addition, each of the above-described embodiments illustrates the structure using TSVs. The same scheme may be provided when a memory chip includes different architectures or when different architectures are present in a memory chip module.

Although not particularly described in each of the above-described embodiments, the memory chip 100 and memory controller 200 may be packaged, or the memory 100 and memory controller 200 may be detachable.

The clock buffer 110, command address buffer 121, mode register 122 and clock comparator 131 of each of the memory chips 100a and 100b may be disposed on an interface layer, and the memory chips 100a and 100b may share the structure disposed on the interface layer. This interface layer may be provided between the memory controller 200 and the memory chip 100.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system including a memory and a controller configured to control the memory,
the memory comprising:
a semiconductor memory region in which data rewrite is executed by an instruction of the controller;
a timing determination module configured to derive a command input timing to the memory, based on the instruction and a clock which are received from the controller; and
a status register configured to store the command input timing to the memory, which is derived by the timing determination module, and
the controller being configured to read out the command input timing from the status register and to issue a command to the memory, based on the command input timing which is acquired.

2. The memory system of claim 1, wherein the timing determination module comprises:
a decoder configured to store a write time of data to the semiconductor memory region, or a read time of data from the semiconductor memory region; and
a comparator configured to derive the command input timing by comparing the time supplied from the decoder and the clock.

3. The memory system of claim 1, wherein the timing determination module is configured to derive the command input timing, based on an ambient temperature of the memory or an operation voltage of the memory.

4. The memory system of claim 1, wherein the controller is configured to cause the timing determination module to derive the command input timing once again, when a frequency of the clock, an ambient temperature or an operation voltage has varied.

5. The memory system of claim 1, wherein the timing determination module is configured to derive a plurality of kinds of command input timings.

6. The memory system of claim 1, further comprising other memories having different command intervals relating to read-out from the semiconductor memory region or write to the semiconductor memory region.

7. The memory system of claim 6, wherein the controller is configured to manage command input timings of the memory and the other memories.

8. The memory system of claim 1, wherein the memory and the controller are connected by a TSV (Through Silicon Via).

9. The memory system of claim 1, wherein the command input timing is a clock number.

10. The memory system of claim 1, wherein the semiconductor memory region includes a plurality of nonvolatile memory elements.

11. The memory system of claim 10, wherein the nonvolatile memory element is a magnetic random access memory (MRAM).

12. A memory comprising:
a semiconductor memory region in which data rewrite is executed by an instruction of a controller;
a timing determination module configured to derive a command input timing to the memory, based on the instruction and a clock which are received from the controller; and
a status register configured to store the command input timing to the memory, which is derived by the timing determination module, and to output the command input timing to the controller, based on the instruction of the controller.

13. The memory of claim 12, wherein the timing determination module comprises:
a decoder configured to store a write time of data to the semiconductor memory region, or a read time of data from the semiconductor memory region; and
a comparator configured to derive the command input timing by comparing the time supplied from the decoder and the clock.

14. The memory of claim 12, wherein the timing determination module is configured to derive the command input timing, based on an ambient temperature of the memory or an operation voltage of the memory.

15. The memory of claim 12, wherein the timing determination module is configured to derive a plurality of kinds of command input timings.

16. The memory of claim 12, wherein the memory and the controller are connected by a TSV (Through Silicon Via).

17. The memory of claim 12, further comprising other memories having different capabilities.

18. The memory of claim 12, wherein the command input timing is a clock number.

19. The memory of claim 12, wherein the semiconductor memory region includes a plurality of resistive elements.

20. The memory of claim 12, wherein the resistive element is a magnetic random access memory (MRAM).
